(19) United States
(12) Patent Application Publication
(10) Pub. No.: US 2026/0088057 A1
(43) Pub. Date: Mar. 26, 2026

(54) SEMICONDUCTOR MEMORY DEVICE

(71) Applicant: Kioxia Corporation, Tokyo (JP)

(72) Inventors: Kiwamu SAKUMA, Yokkaichi (JP); Yasunao OTSUKI, Yokkaichi (JP); Ryosuke SAWABE, Yokkaichi (JP); Kunifumi SUZUKI, Yokkaichi (JP); Rieko FUNATSUKI, Yokohama (JP)

(73) Assignee: Kioxia Corporation, Tokyo (JP)

(21) Appl. No.: 19/068,514

(22) Filed: Mar. 3, 2025

(30) Foreign Application Priority Data
Sep. 20, 2024 (JP) 2024-163246

(51) Int. Cl. G11C 5/06; H10B 51/10; H10B 51/20; H10D 30/69

(52) U.S. Cl. CPC G11C 5/063; H10B 51/10; H10B 51/20; H10D 30/701

(57) ABSTRACT

According to one embodiment, a semiconductor memory device including multiple first memory cells and a first selection mechanism is provided. The multiple first memory cells are stacked above a substrate. The multiple first memory cells are connected in parallel between a first vertical bit line and a first vertical source line. The first vertical bit line extends in a stacking direction. The first vertical source line extends in the stacking direction. The first selection mechanism is disposed between the substrate and the multiple first memory cells in the stacking direction. The first selection mechanism selectively connects the first vertical bit line to a first local bit line. The first selection mechanism selectively connects the first vertical source line to a first local source line.

### CROSS-REFERENCE TO RELATED APPLICATIONS

This application is based upon and claims the benefit of Japanese Patent Application No. 2024-163246, filed on Sep. 20, 2024; the entire contents of which are incorporated herein by reference.

### FIELD

Embodiments described herein relate generally to a semiconductor memory device.

### BACKGROUND

In a semiconductor memory device including multiple memory cells connected in parallel between a bit line and a source line, selection potentials of the bit line and the source line can be supplied to the memory cells via a selection mechanism. It is desirable that the selection mechanism for the memory cells is appropriately configured in the semiconductor memory device.

### BRIEF DESCRIPTION OF THE DRAWINGS

FIG. 1 is a perspective view illustrating a configuration of a semiconductor memory device according to an embodiment;

FIG. 2 is a block diagram illustrating a configuration of the semiconductor memory device according to the embodiment;

FIG. 3 is a circuit diagram illustrating a configuration of a memory cell array according to the embodiment;

FIG. 4 is a circuit diagram illustrating configurations of a memory cell and selection mechanisms according to the embodiment;

FIG. 5 is a plan view illustrating a configuration of an array layer according to the embodiment;

FIG. 6 is a cross-sectional view illustrating configurations of the array layer and a select gate layer according to the embodiment;

FIG. 7 is a plan view illustrating a configuration of the select gate layer according to the embodiment;

FIG. 8 is a cross-sectional view illustrating configurations of the array layer and the select gate layer according to the embodiment;

FIG. 9 is a plan view illustrating a configuration of the select gate layer according to the embodiment;

FIG. 10 is a cross-sectional view illustrating configurations of an array layer and a select gate layer according to a first modified example of the embodiment;

FIG. 11 is a plan view illustrating a configuration of the select gate layer according to the first modified example of the embodiment;

FIG. 12 is a cross-sectional view illustrating configurations of an array layer and a select gate layer according to a second modified example of the embodiment;

FIG. 13 is a plan view illustrating a configuration of the select gate layer according to the second modified example of the embodiment;

FIG. 14 is a cross-sectional view illustrating configurations of an array layer and a select gate layer according to a third modified example of the embodiment;

FIG. 15 is a plan view illustrating a configuration of a select gate layer and an operation of the select gate layer when writing “1” according to a fourth modified example of the embodiment;

FIG. 16 is an enlarged plan view illustrating an operation of a selected memory cell when writing “1” according to the fourth modified example of the embodiment;

FIG. 17 is an enlarged plan view illustrating an operation of an unselected memory cell when writing “1” according to the fourth modified example of the embodiment;

FIG. 18 is a plan view illustrating an operation of the select gate layer when writing “0” according to the fourth modified example of the embodiment;

FIG. 19 is an enlarged plan view illustrating an operation of the selected memory cell when writing “0” according to the fourth modified example of the embodiment;

FIG. 20 is an enlarged plan view illustrating an operation of the unselected memory cell when writing “0” according to the fourth modified example of the embodiment;

FIG. 21 is a plan view illustrating an operation of the select gate layer when reading according to the fourth modified example of the embodiment;

FIG. 22 is an enlarged plan view illustrating an operation of the selected memory cell when reading according to the fourth modified example of the embodiment; and

FIG. 23 is an enlarged plan view illustrating an operation of the unselected memory cell when reading according to the fourth modified example of the embodiment.

### DETAILED DESCRIPTION

In general, according to one embodiment, there is provided a semiconductor memory device including multiple first memory cells and a first selection mechanism. The multiple first memory cells are stacked above a substrate and connected in parallel between a first vertical bit line extending in a stacking direction and a first vertical source line extending in the stacking direction. The first selection mechanism is disposed between the substrate and the multiple first memory cells in the stacking direction, selectively connects the first vertical bit line to a first local bit line, and selectively connects the first vertical source line to a first local source line.

Exemplary embodiments of a semiconductor memory device will be explained below in detail with reference to the accompanying drawings. The present invention is not limited to the following embodiments.

### Embodiment

The semiconductor memory device according to the embodiment includes multiple memory cells connected in parallel between a bit line and a source line and is capable of supplying selection potentials of the bit line and the source line to the memory cells via a selection mechanism, and improvements are made to appropriately configure the selection mechanism.

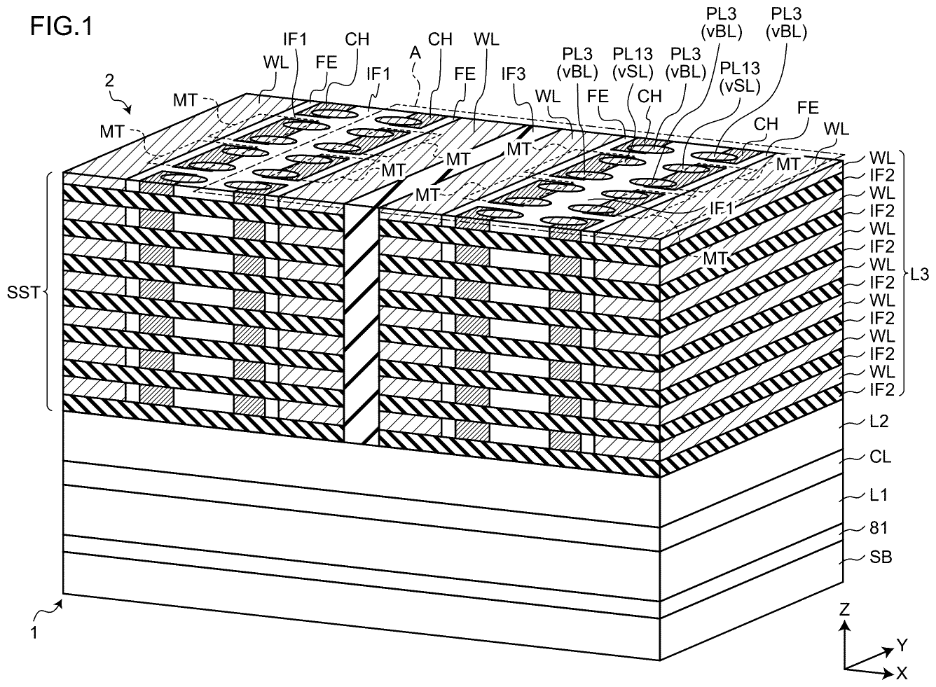

A semiconductor memory device 1 can be configured as illustrated in FIG. 1. FIG. 1 is a perspective view illustrating a configuration of the semiconductor memory device 1. Hereinafter, a direction perpendicular to a surface of a substrate SB is referred to as a Z direction, and two directions orthogonal to each other in a plane perpendicular to the Z direction are referred to as an X direction and a Y direction.

The semiconductor memory device 1 is a three-dimensional memory, for example, a ferroelectric memory. The semiconductor memory device 1 includes the substrate SB, a select gate layer L1, a connection layer CL, a select gate layer L2, and an array layer L3. The select gate layer L1, the connection layer CL, the select gate layer L2, and the array layer L3 are sequentially stacked on the substrate SB.

The array layer L3 includes a memory cell array 2, a word line WL, a columnar body PL3, and a columnar body PL13.

The substrate SB extends in a plate shape in the X direction and the Y direction. The substrate SB can be made of a material containing a semiconductor (for example, silicon) as a main component. Multiple word lines WL are stacked while being spaced apart from each other in the Z direction above (on +Z side of) the substrate SB. Multiple insulating layers IF2 and the multiple word lines WL may be alternately provided above the substrate SB. The multiple word lines WL are arranged while being spaced apart from each other in the X direction at the same Z position. Each word line WL extends mainly in the Y direction. Each word line WL may have a plate shape having a main surface in the X direction and the Y direction. Each word line WL can be made of, for example, a material containing a metal such as tungsten as a main component. The insulating layer IF2 can be made of a material containing a semiconductor oxide (for example, silicon oxide) as a main component.

The memory cell array 2 includes multiple channel regions CH and multiple insulating films FE.

The multiple channel regions CH are stacked while being spaced apart from each other in the Z direction on the +Z side of the substrate SB. The multiple insulating layers IF2 and the multiple channel regions CH may be alternately provided. The multiple channel regions CH are arranged in the X direction, the Y direction, and the Z direction.

The multiple channel regions CH that are adjacent to each other in the X direction and the Y direction between the multiple word lines WL are electrically separated from each other by an insulating film IF1. The multiple channel regions CH that are adjacent to each other in the X direction across the multiple word lines WL are electrically separated from each other by a slit IF3. The slit IF3 can be made of a material containing a semiconductor oxide (for example, silicon oxide) as a main component. The multiple channel regions CH that are adjacent to each other in the Z direction are electrically separated from each other by the insulating layer IF2.

Each channel region CH extends in a plate shape in the X direction and the Y direction. Each channel region CH can be formed using a semiconductor film containing a semiconductor (for example, silicon) as a main component.

The multiple insulating films FE are stacked while being spaced apart from each other in the Z direction on the +Z side of the substrate SB. The multiple insulating layers IF2 and the multiple insulating films FE may be alternately provided. The multiple insulating films FE are arranged in the X direction. Each insulating film FE is disposed between the word line WL and the channel region CH in the X direction. Each insulating film FE extends linearly in the Y direction. Each insulating film FE can be made of an insulator. Each insulating film FE may include a ferroelectric.

Each insulating film FE can be made of a material containing hafnium oxide (HfO) as a main component. Each insulating film FE may be made of a material further containing at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

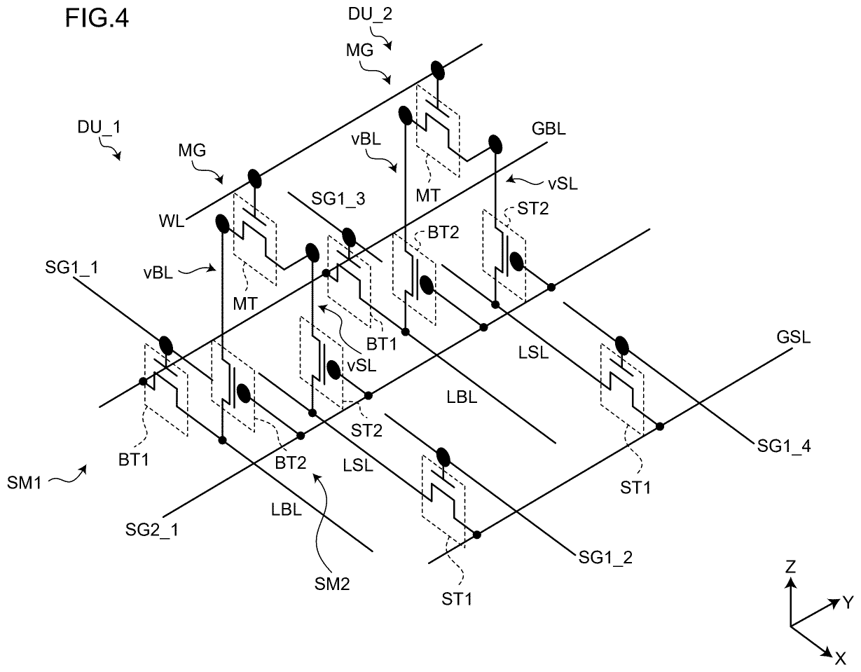

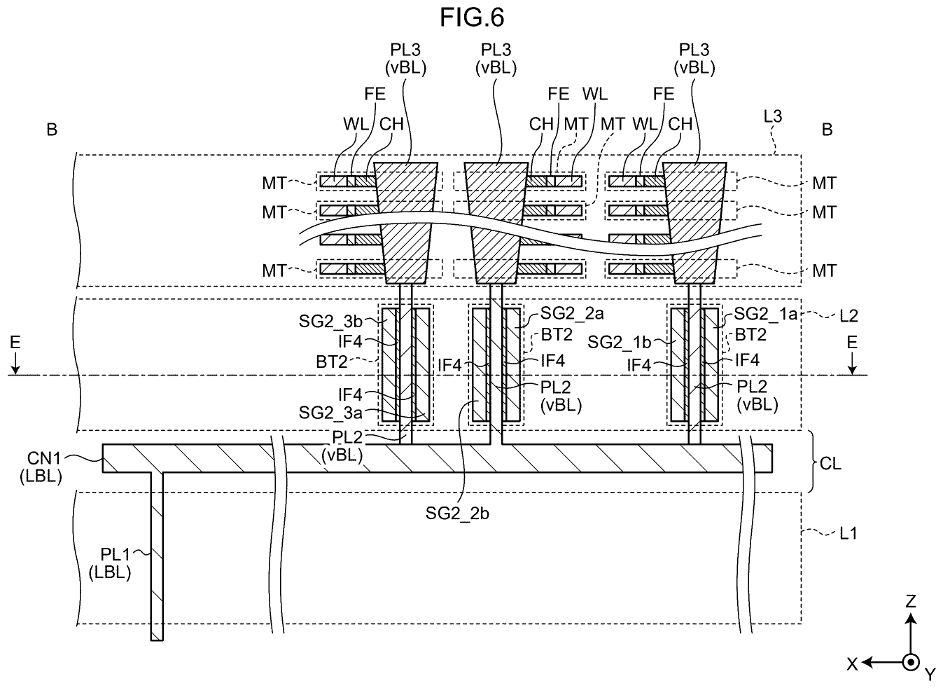

Multiple columnar bodies PL3 are arranged in the X direction and the Y direction on the +Z side of the substrate SB. The arrangement of the multiple columnar bodies PL3 in the X direction and the Y direction corresponds to the arrangement of the multiple channel regions CH in the X direction and the Y direction. Each columnar body PL3 corresponds to the multiple channel regions CH arranged in the Z direction. Each columnar body PL3 penetrates through the multiple channel regions CH arranged in the Z direction, extends in the Z direction which is the stacking direction of the multiple channel regions CH, and reaches the channel region CH that is closest to a −Z side (see FIG. 6). Each columnar body PL3 extends in the Z direction in the channel region CH. Each columnar body PL3 can be made of, for example, a material containing a metal such as tungsten as a main component. The columnar body PL3 functions as a part of a vertical bit line vBL (see FIG. 4). The vertical bit line vBL can be connected to a global bit line GBL via a local bit line LBL.

Multiple columnar bodies PL13 are arranged in the X direction and the Y direction on the +Z side of the substrate SB. The arrangement of the multiple columnar bodies PL13 in the X direction and the Y direction corresponds to the arrangement of the multiple channel regions CH in the X direction and the Y direction, and corresponds to the arrangement of the multiple columnar bodies PL3 in the X direction and the Y direction. Each columnar body PL13 corresponds to the multiple channel regions CH arranged in the Z direction. Each columnar body PL13 penetrates through multiple corresponding channel regions CH at a position spaced apart from the columnar body PL3 in the Y direction, extends in the Z direction which is the stacking direction of the multiple channel regions CH, and reaches the channel region CH that is closest to the −Z side (see FIG. 6). Each columnar body PL13 extends in the Z direction in the channel region CH. Each columnar body PL13 can be made of, for example, a material containing a metal such as tungsten as a main component. The columnar body PL13 functions as a part of a vertical source line vSL (see FIG. 4). The vertical source line vSL can be connected to a global source line GSL via a local source line LSL.

In the array layer L3, a stacked body SST in which “the word line WL, the insulating film FE, the channel region CH”, and the insulating layer IF2 are alternately stacked is formed. In the stacked body SST, the multiple channel regions CH are arranged in the X direction, the Y direction, and the Z direction, and each channel region CH is adjacent to the insulating film FE and the word line WL in this order in the X direction to form a three-dimensional arrangement (memory cell array) of memory cells MT.

That is, in the semiconductor memory device 1, a portion of the channel region CH that faces the word line WL via the insulating film FE is configured to function as the memory cell MT, and the memory cell array 2 in which the multiple memory cells MT are three-dimensionally arranged is formed. In the semiconductor memory device 1, a storage capacity can be increased without using a finer patterning technology, by increasing the number of stacked word lines WL in the stacked body SST.

A selection mechanism SM2 (see FIG. 4) is disposed in the select gate layer L2. The selection mechanism SM2 includes a select transistor BT2 and a select transistor ST2. Each of the select transistor BT2 and the select transistor ST2 is driven via a select gate line SG2 connected to a gate thereof.

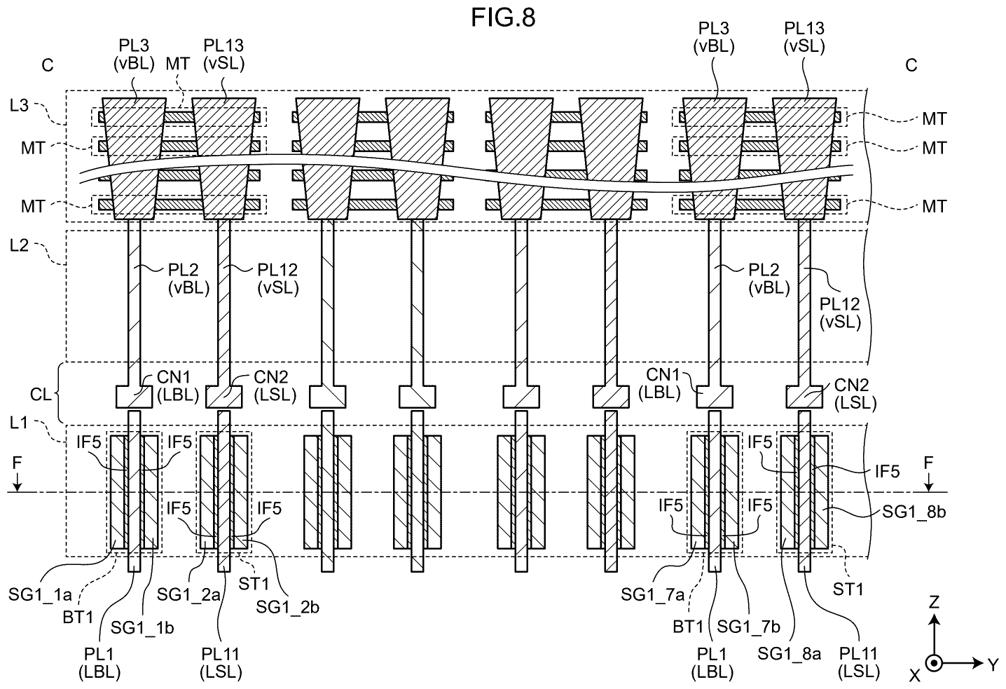

A conductive film CN1 and a conductive film CN2 (see FIGS. 6 and 8) are disposed in the connection layer CL. Each of the conductive film CN1 and the conductive film CN2 can be made of, for example, a material containing a metal such as aluminum or copper as a main component. The conductive film CN1 functions as a part of the local bit line LBL (see FIG. 4). The conductive film CN2 functions as a part of the local source line LSL (see FIG. 4).

A selection mechanism SM1 (see FIG. 4) is disposed in the select gate layer L1. The selection mechanism SM1 includes a select transistor BT1 and a select transistor ST1. Each of the select transistor BT1 and the select transistor ST1 is driven via a select gate line SG1 connected to a gate thereof.

An interlayer insulating film 81 may be interposed between the substrate SB and the select gate layer L1 in the Z direction. The interlayer insulating film 81 can be made of a material containing a semiconductor oxide (for example, silicon oxide) as a main component.

A selection potential of the global bit line GBL can be supplied to the memory cell MT via the selection mechanism SM1, the local bit line LBL, the selection mechanism SM2, and the vertical bit line vBL. A selection potential of the global source line GSL can be supplied to the memory cell MT via the selection mechanism SM1, the local source line LSL, the selection mechanism SM2, and the vertical bit line vBL.

For example, when manufacturing the semiconductor memory device 1, a structure of the select gate layer L1, a structure of the connection layer CL, a structure of the select gate layer L2, and a structure of the array layer L3 are formed substantially in this order on the +Z side of the substrate SB. When forming the structure (selection mechanism SM1) of the select gate layer L1 and the structure (selection mechanism SM2) of the select gate layer L2, heat treatment at a relatively high temperature (for example, 1000° C. or higher) is performed. In a case where each insulating film FE includes the ferroelectric, when each insulating film FE is subjected to the heat treatment, ferroelectricity of each insulating film FE is lost (paraelectric), and it becomes difficult to hold “1” or “0” in a polarization direction thereof.

On the other hand, in the semiconductor memory device 1, the selection mechanisms SM1 and SM2 of the memory cells MT are disposed between the substrate SB and the memory cell array 2 in the Z direction as illustrated in FIG. 1. As a result, in a manufacturing process for the semiconductor memory device 1, the structure of the array layer L3 is formed after the heat treatment at a relatively high temperature is completed. Therefore, a structure of the semiconductor memory device 1 is a structure suitable for avoiding the heat treatment from being applied to each insulating film FE in a case where each insulating film FE includes the ferroelectric.

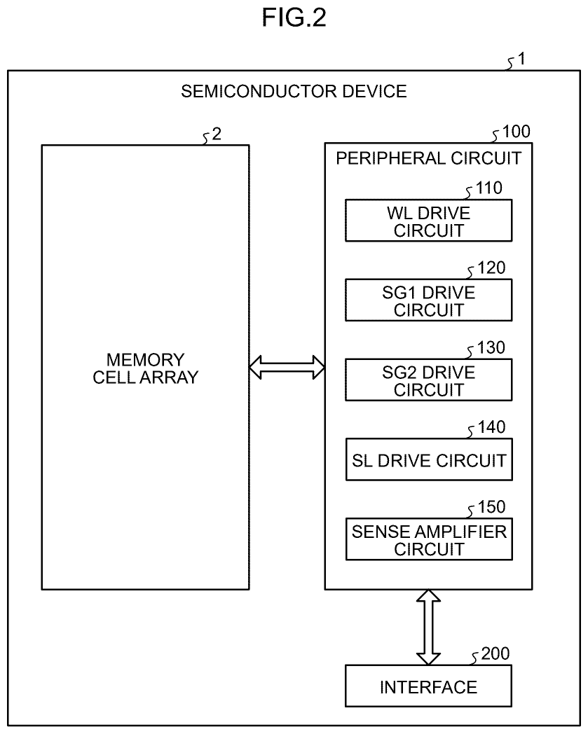

FIG. 2 is a block diagram illustrating a schematic configuration of the semiconductor memory device 1. As illustrated in FIG. 2, the semiconductor memory device 1 includes the memory cell array 2, a peripheral circuit 100, and an interface 200. The peripheral circuit 100 includes a WL drive circuit 110, an SG1 drive circuit 120, an SG2 drive circuit 130, an SL drive circuit 140, and a sense amplifier circuit 150.

The WL drive circuit 110 is a circuit that controls a voltage applied to the word line WL, and the SG1 drive circuit 120 is a circuit that controls a voltage applied to the select gate line SG1. The SG2 drive circuit 130 is a circuit that controls a voltage applied to the select gate line SG2, and the SL drive circuit 140 is a circuit that controls a voltage applied to the global source line GSL. The sense amplifier circuit 150 is a circuit that controls a voltage applied to the global bit line GBL and is a circuit that determines read data according to a signal from a selected memory cell.

The peripheral circuit 100 controls an operation of the semiconductor memory device 1 based on an instruction input from the outside (for example, a memory controller of a memory system to which the semiconductor memory device 1 is applied) via the interface 200.

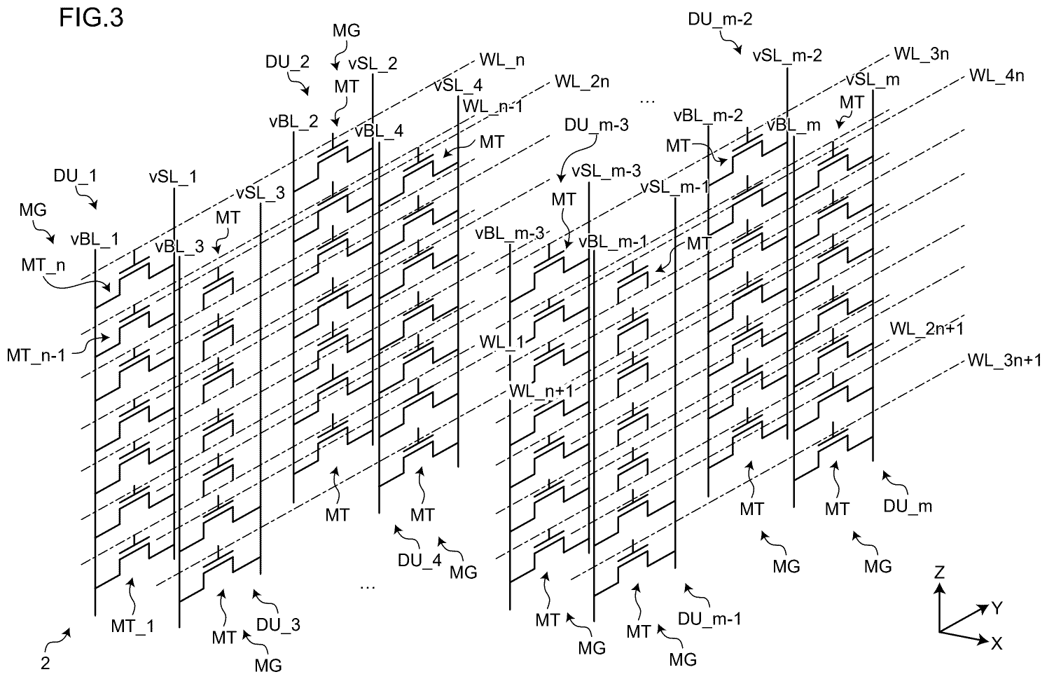

Next, a circuit configuration of the memory cell array 2 will be described with reference to FIG. 3. FIG. 3 is a diagram three-dimensionally illustrating the circuit configuration of the memory cell array 2.

In FIG. 3, for example, 4n (n is an integer of 2 or more) word lines WL_1 to WL_4n are provided in the memory cell array 2. In the memory cell array 2, m (m is a multiple of 2 or more) vertical bit lines vBL_1 to vBL_m and m vertical source lines vSL_1 to vSL_m are provided.

In the memory cell array 2, the multiple memory cells MT are implemented by NOR-type circuits.

The memory cell array 2 can be divided into m drive units DU_1 to DU_m. The m drive units DU_1 to DU_m are arranged in the X direction and the Y direction. In FIG. 3, an arrangement of 2 rows×2/m columns is exemplified as the arrangement of the drive units DU. Each drive unit DU includes n memory cells MT sharing the vertical bit line vBL and the vertical source line vSL. The n memory cells MT are arranged in the Z direction.

In the drive unit DU, the n memory cells MT are connected in parallel between the vertical bit line vBL and the vertical source line vSL to form a NOR-type memory cell group MG.

The word line WL is connected across the drive units DU arranged in the Y direction. The word line WL is connected to gates of the multiple memory cells MT arranged in the Y direction.

As illustrated in FIG. 4, the selection mechanisms SM1 and SM2 are provided on −Z sides of the vertical bit line vBL and the vertical source line vSL. FIG. 4 is a circuit diagram illustrating configurations of the memory cell MT and the selection mechanisms SM1 and SM2. For the sake of simplicity, FIG. 4 illustrates one memory cell MT in the memory cell group MG of each of the drive units DU_1 and DU_2 and does not illustrate other memory cells MT in the memory cell group MG.

As the selection mechanism SM1, the select transistor BT1 and the select transistor ST1 are provided. As the selection mechanism SM2, the select transistor BT2 and the select transistor ST2 are provided.

The select transistor BT1 is connected between the local bit line LBL and the global bit line GBL. The select transistor BT1 has a drain connected to the local bit line LBL, a source connected to the global bit line GBL, and the gate connected to the select gate line SG1. The select transistor BT1 is driven via the select gate line SG1 connected to the gate of the select transistor BT1.

The select transistor BT2 is connected between the vertical bit line vBL and the local bit line LBL. The select transistor BT2 has a drain connected to the vertical bit line vBL, a source connected to the local bit line LBL, and the gate connected to the select gate line SG2. The select transistor BT2 is driven via the select gate line SG2 connected to the gate of the select transistor BT2.

The select transistor ST1 is connected between the local source line LSL and the global source line GSL. The select transistor ST1 has a drain connected to the local source line LSL, a source connected to the global source line GSL, and the gate connected to the select gate line SG1. The select transistor ST1 is driven via the select gate line SG1 connected to the gate of the select transistor ST1.

The select transistor ST2 is connected between the vertical source line vSL and the local source line LSL. The select transistor ST2 has a drain connected to the vertical source line vSL, a source connected to the local source line LSL, and the gate connected to the select gate line SG2. The select transistor ST2 is driven via the select gate line SG2 connected to the gate of the select transistor ST2.

In the memory cell group MG, the global bit line GBL is selectively connected in two stages by the select transistor BT1 and the select transistor BT2. The global source line GSL is selectively connected in two stages by the select transistor ST1 and the select transistor ST2. The memory cell MT in the selected memory cell group MG is selected by the word line WL.

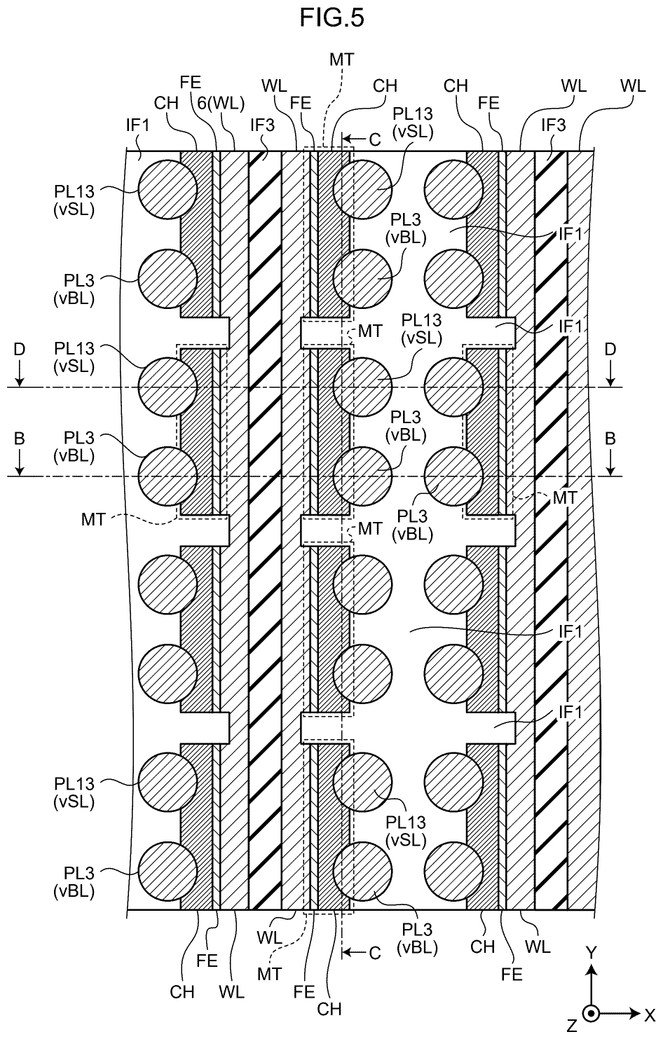

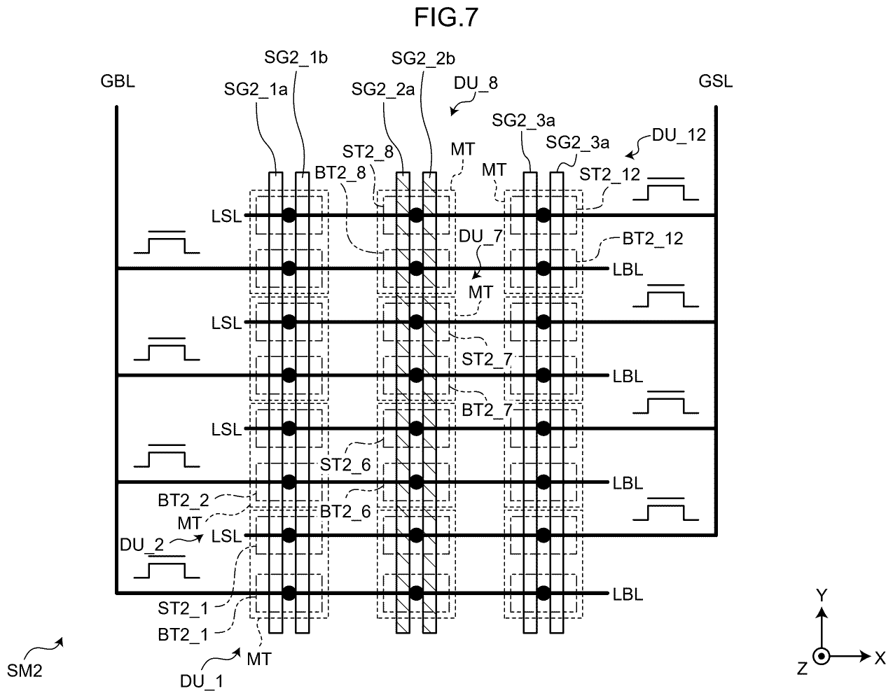

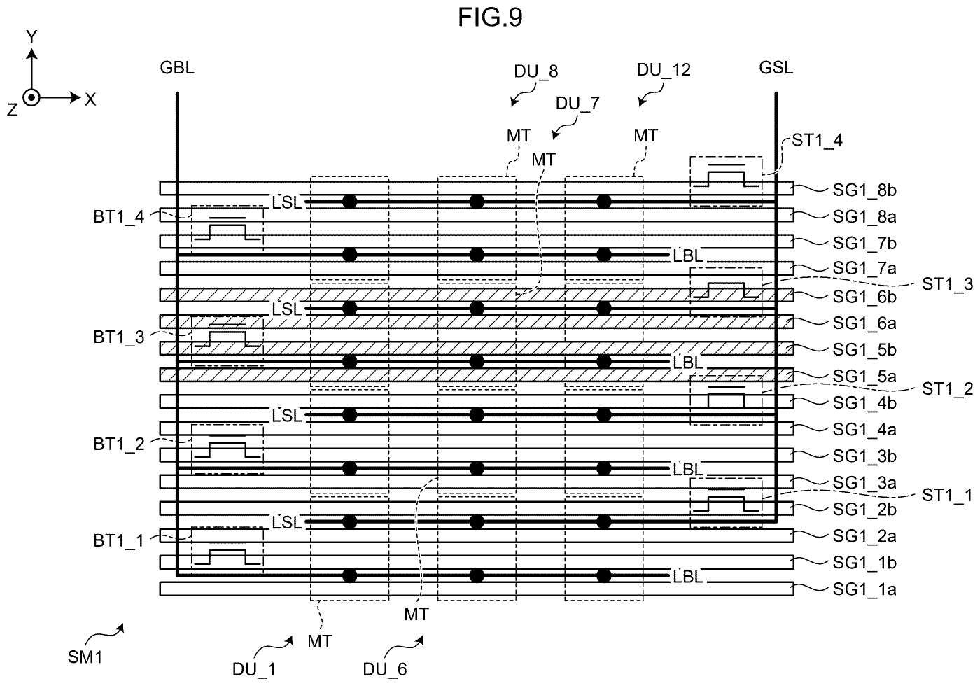

Next, detailed configurations of the array layer L3, the select gate layer L2, and the select gate layer L1 will be described with reference to FIGS. 5 to 9. FIG. 5 is a plan view illustrating a configuration of the array layer L3 along an X-Y plane and is an enlarged plan view corresponding to a portion A in FIG. 1 along the X-Y plane. FIG. 6 is a cross-sectional view illustrating configurations of the array layer L3, the select gate layer L2, and the select gate layer L1 along an X-Z plane and illustrates a cross section taken along line B-B in FIG. 5. FIG. 7 is a plan view illustrating a configuration of the select gate layer L2 along the X-Y plane and corresponds to a cross section taken along line E-E in FIG. 6. FIG. 8 is a cross-sectional view illustrating configurations of the array layer L3, the select gate layer L2, and the select gate layer L1 along a Y-Z plane and illustrates a cross section taken along line C-C in FIG. 5. FIG. 9 is a plan view illustrating a configuration of the select gate layer L1 along the X-Y plane and corresponds to a cross section taken along line F-F in FIG. 8.

As illustrated in FIGS. 5, 6, and 8, in the array layer L3, a portion of the channel region CH that faces the word line WL via the insulating film FE is configured to function as the memory cell MT, and the memory cell array 2 in which the multiple memory cells MT are three-dimensionally arranged is formed. In the memory cell array 2, the multiple memory cells MT are grouped into multiple memory cell groups each corresponding to the drive unit DU (see FIG. 3). Each memory cell group includes the multiple memory cells MT arranged in the Z direction. The multiple memory cell groups are arranged in the X direction and the Y direction.

The multiple memory cell groups correspond to the multiple columnar bodies PL3 and correspond to the multiple columnar bodies PL13. In the channel region CH of each memory cell group, the corresponding columnar body PL3 extends in the Z direction, and the corresponding columnar body PL13 extends in the Z direction. Each columnar body PL3 can be made of, for example, a material containing a metal such as tungsten as a main component. The columnar body PL3 functions as a part of the vertical bit line vBL (see FIG. 4). Each columnar body PL13 can be made of, for example, a material containing a metal such as tungsten as a main component. The columnar body PL13 functions as a part of the vertical source line vSL (see FIG. 4).

As illustrated in FIGS. 6 and 7, multiple columnar bodies PL2, multiple columnar bodies PL12, multiple select gate lines SG2_1 to SG2_3, and multiple insulating films IF4 are disposed in the select gate layer L2. The select gate line SG2_1 includes multiple conductive films SG2_1a and SG2_1b. The select gate line SG2_2 includes multiple conductive films SG2_2a and SG2_2b. The select gate line SG2_3 includes multiple conductive films SG2_3a and SG2_3b.

The multiple columnar bodies PL2 correspond to the multiple columnar bodies PL3 and correspond to multiple conductive films CN1. Each columnar body PL2 extends in the Z direction. A +Z-side end portion of each columnar body PL2 is connected to the corresponding columnar body PL3. A −Z-side end portion of each columnar body PL2 is connected to the corresponding conductive film CN1 (local bit line LBL).

The multiple columnar bodies PL12 correspond to the multiple columnar bodies PL13 and correspond to multiple conductive films CN2. Each columnar body PL12 extends in the Z direction. A +Z-side end portion of each columnar body PL12 is connected to the corresponding columnar body PL13. A −Z-side end portion of each columnar body PL12 is connected to the corresponding conductive film CN2 (local source line LSL).

The multiple conductive films SG2_1a to SG2_3b correspond to the multiple columnar bodies PL2 and PL12 arranged in the Y direction. Each conductive film SG2 extends in the Y direction. Each conductive film SG2 can be made of, for example, a material containing a metal such as tungsten as a main component.

As the conductive film SG2_1a illustrated in FIG. 7 advances from a −Y side to a +Y side, the conductive film SG2_1a alternately approaches a −X-side surface of the columnar body PL2 and a −X-side surface of the columnar body PL12 multiple times. The insulating film IF4 is interposed between the conductive film SG2_1a and the columnar bodies PL2 and PL12 at positions close to the respective columnar bodies PL2 and PL12. The insulating film IF4 can be made of a material containing a semiconductor oxide (for example, silicon oxide) as a main component. As the conductive film SG2_1b advances from the −Y side to the +Y side, the conductive film SG2_1b alternately approaches a +X-side surface of the columnar body PL2 and a +X-side surface of the columnar body PL12 multiple times. The insulating film IF4 is interposed between the conductive film SG2_1b and the columnar bodies PL2 and PL12 at positions close to the respective columnar bodies PL2 and PL12.

The conductive film SG2_1a and the conductive film SG2_1b form a pair and function as the select gate line SG2_1 (see FIG. 4) in cooperation with each other. A portion of the columnar body PL2 that faces each of the conductive films SG2_1a and SG2_1b via the insulating film IF4 functions as the select transistor BT2. The select transistor BT2 has a vertical thin film transistor (TFT) structure in which a channel region extends in the Z direction and gates are provided on both sides in the X direction.

A portion of the columnar body PL12 that faces each of the conductive films SG2_1a and SG2_1b via the insulating film IF4 functions as the select transistor ST2. The select transistor ST2 has a vertical thin film transistor (TFT) structure in which a channel region extends in the Z direction and gates are provided on both sides in the X direction.

Each of the pair of conductive films SG2_2a and SG2_2b and the pair of conductive films SG2_3a and SG2_3b is similar to the pair of conductive films SG2_1a and SG2_1b.

As illustrated in FIGS. 6 to 9, the multiple conductive films CN1 and the multiple conductive films CN2 are disposed in the connection layer CL. Each conductive film CN1 functions as a part of the local bit line LBL illustrated in FIGS. 7 and 9, and functions as, for example, a portion from a +X-side end portion of the local bit line LBL to the immediate vicinity of a +X side of the select transistor BT1. The multiple conductive films CN1 are arranged in the Y direction, and each conductive film CN1 extends in the X direction. Each conductive film CN2 functions as a part of the local source line LSL illustrated in FIGS. 7 and 9, and functions as, for example, a portion from a −X-side end portion of the local source line LSL to the immediate vicinity of a −X side of the select transistor ST1. The multiple conductive films CN2 are arranged in the X direction, and each conductive film CN2 extends in the Y direction.

As illustrated in FIGS. 8 and 9, multiple columnar bodies PL1, multiple columnar bodies PL11, multiple select gate lines SG1_1 to SG1_8, and multiple insulating films IF5 are disposed in the select gate layer L1. The select gate line SG1_1 includes multiple conductive films SG1_1a and SG1_1b. The select gate line SG1_2 includes multiple conductive films SG1_2a and SG1_2b. The select gate line SG1_3 includes multiple conductive films SG1_3a and SG1_3b. The select gate line SG1_4 includes multiple conductive films SG1_4a and SG1_4b. The select gate line SG1_5 includes multiple conductive films SG1_5a and SG1_5b. The select gate line SG1_6 includes multiple conductive films SG1_6a and SG1_6b. The select gate line SG1_7 includes multiple conductive films SG1_7a and SG1_7b. The select gate line SG1_8 includes multiple conductive films SG1_8a and SG1_8b.

The multiple columnar bodies PL1 correspond to the multiple conductive films CN1. Each columnar body PL1 extends in the Z direction. A +Z-side end portion of each columnar body PL1 is connected to the corresponding conductive film CN1 (local bit line LBL). A −Z-side end portion of each columnar body PL1 is connected to the global bit line GBL.

The multiple columnar bodies PL1l correspond to the multiple conductive films CN2. Each columnar body PL1l extends in the Z direction. A +Z-side end portion of each columnar body PL1l is connected to the corresponding conductive film CN2. A −Z-side end portion of each columnar body PL12 is connected to the global source line GSL.

The multiple conductive films SG1_1a to SG1_8b correspond to the multiple columnar bodies PL1 and PL1l arranged in the Y direction. Each conductive film SG1 extends in the X direction. Each conductive film SG1 can be made of, for example, a material containing a metal such as tungsten as a main component.

As the conductive film SG1_1a illustrated in FIG. 9 advances from a −X side to a +X side, the conductive film SG1_1a alternately approaches a −Y-side surface of the columnar body PL1 and a −Y-side surface of the columnar body PL1l multiple times. The insulating film IF5 is interposed between the conductive film SG1_1a and the columnar bodies PL1 and PL1l at positions close to the respective columnar bodies PL1 and PL1l. The insulating film IF5 can be made of a material containing a semiconductor oxide (for example, silicon oxide) as a main component. As the conductive film SG1_1b advances from the −X side to the +X side, the conductive film SG1_1b alternately approaches a +Y-side surface of the columnar body PL1 and a +Y-side surface of the columnar body PL1l multiple times. The insulating film IF5 is interposed between the conductive film SG1_1b and the columnar bodies PL1 and PL1l at positions close to the respective columnar bodies PL1 and PL11.

A portion of the columnar body PL1 that faces each of the conductive films SG1_1a and SG1_1b via the insulating film IF5 functions as the select transistor BT1. The select transistor BT1 has a vertical thin film transistor (TFT) structure in which a channel region extends in the Z direction and gates are provided on both sides in the Y direction.

A portion of the columnar body PL11 that faces each of the conductive films SG1_1a and SG1_1b via the insulating film IF5 functions as the select transistor ST1. The select transistor ST1 has a vertical thin film transistor (TFT) structure in which a channel region extends in the Z direction and gates are provided on both sides in the Y direction.

It should be noted that each of the pair of conductive films SG2_2a and SG2_2b, the pair of conductive films SG2_3a and SG2_3b, a pair of conductive films SG2_4a and SG2_4b, a pair of conductive films SG2_5a and SG2_5b, a pair of conductive films SG2_6a and SG2_6b, a pair of conductive films SG2_7a and SG2_7b, and a pair of conductive films SG2_8a and SG2_8b is similar to the pair of conductive films SG2_1a and SG2_1b. For example, the pair of conductive films SG2_2a and SG2_2b, the pair of conductive films SG2_3a and SG2_3b, the pair of conductive films SG2_4a and SG2_4b, the pair of conductive films SG2_5a and SG2_5b, the pair of conductive films SG2_6a and SG2_6b, the pair of conductive films SG2_7a and SG2_7b, and the conductive films SG2_8a and SG2_8b cooperate to function as the select gate line SG1_2, the select gate line SG1_3, the select gate line SG1_4, the select gate line SG1_5, the select gate line SG1_6, the select gate line SG1_7, and the select gate line SG1_8, respectively.

FIGS. 7 and 9 illustrate the arrangement of the selection mechanism SM2 and the selection mechanism SM1 in a case where the multiple drive units DU_1 to DU_12 are arranged in 4 rows×3 columns, respectively.

In FIG. 7, select transistors BT2_1 to BT2_12 and select transistors ST2_1 to ST2_12 are illustrated as the selection mechanism SM2. The select transistors BT2_1 to BT2_12 correspond to the drive unit DU and are arranged in 4 rows×3 columns. The select transistors ST2_1 to ST2_12 correspond to the drive unit DU and are arranged in 4 rows×3 columns.

In FIG. 9, select transistors BT1_1 to BT1_4 and select transistors ST1_1 to ST1_4 are illustrated as the selection mechanism SM1. The select transistors BT1_1 to BT1_12 correspond to the local bit line LBL and are arranged in 4 rows×1 column on a −X side of the arrangement of the multiple drive units DU_1 to DU_12. The select transistors ST1_1 to ST1_4 correspond to the local source line LSL and are arranged in 4 rows×1 column on a +X side of the arrangement of the multiple drive units DU_1 to DU_12.

The local bit line LBL and the local source line LSL are alternately arranged multiple times in the Y direction. The global bit line GBL is arranged on the −X side of the arrangement of the multiple drive units DU_1 to DU_12 and extends in the Y direction. The global source line GSL is arranged on the +X side of the arrangement of the multiple drive units DU_1 to DU_12 and extends in the Y direction.

For example, it is assumed that a memory cell MT_n (see FIG. 3) of the drive unit DU_7 illustrated in FIGS. 7 and 9 is selected, and the other memory cells MT_1 to MT_n−1 of the drive unit DU_7 and all the memory cells MT of the other drive units DU_1 to DU_6 and DU_8 to DU_12 are unselected.

In a case where an operation of writing “1” to the selected memory cell MT_n of the drive unit DU_7 is performed, a selection potential of “1” (for example, −2.5 V) is applied to the word line WL_n of the selected memory cell MT_n, and a non-selection potential (for example, 0 V) is applied to the word lines WL_1 to WL_n−1 of the unselected memory cells MT_1 to MT_n−1. The global bit line GBL and the global source line GSL are each controlled to the selection potential of “1” (for example, 2.5 V).

The select gate lines SG1_5a, SG1_5b, SG1_6a, and SG1_6b and the select gate lines SG2_2a and SG2_2b indicated by hatching in FIGS. 7 and 9 correspond to the selected memory cell MT_n. The select gate lines SG1_5a, SG1_5b, SG1_6a, and SG1_6b and the select gate lines SG2_2a and SG2_2b are each controlled to the selection potential (for example, 1.5 V), and the other select gate lines SG1_1a to SG1_4b, SG1_7a to SG1_8b and the other select gate lines SG2_1a, SG2_1b, SG2_3a, and SG2_3b are controlled to the non-selection potential (for example, 0 V).

As a result, each of the select transistors BT1 and BT2 of the drive unit DU_7 is selectively turned on, and the selection potential of the global bit line GBL is supplied to the selected memory cell MT_n of the drive unit DU_7 via the select transistors BT1 and BT2. Each of the select transistors ST1 and ST2 of the drive unit DU_7 is selectively turned on, and the selection potential of the global source line GSL is supplied to the selected memory cell MT_n of the drive unit DU_7 via the select transistors ST1 and ST2.

Accordingly, the channel region CH of the selected memory cell MT_n of the drive unit DU_7 is set to the selection potential (for example, 2.5 V), and in the selected memory cell MT_n of the drive unit DU_7, an electric field (for example, 5 V) exceeding a threshold at which the word line WL_n becomes positive with respect to the channel region CH toward a positive side is applied to the insulating film FE, and writing in which Vth shifts to a negative side occurs in the memory cell MT. “1” can be written to the memory cell MT_n of the drive unit DU_7. The memory cell MT_n can hold “1” if a polarization state does not change due to an external electric field or the like.

At this time, in the unselected memory cells MT_1 to MT_n−1 of the selected drive unit DU_7, the selection potentials of the global bit line GBL and the global source line GSL are supplied, but an electric field (for example, 2.5 V) falling below the threshold to the positive side is applied to the insulating film FE, and writing does not occur in the memory cell MT.

Alternatively, in a case where an operation of writing “0” to the selected memory cell MT_n of the drive unit DU_7 is performed, the selection potential of “0” (for example, 2.5 V) is applied to the word line WL_n of the selected memory cell MT_n, and the non-selection potential (for example, 0 V) is applied to the word lines WL_1 to WL_n−1 of the unselected memory cells MT_1 to MT_n−1. The global bit line GBL and the global source line GSL are each controlled to the selection potential of “0” (for example, −2.5 V).

The select gate lines SG1_5a, SG1_5b, SG1_6a, and SG1_6b and the select gate lines SG2_2a and SG2_2b indicated by hatching in FIGS. 7 and 9 correspond to the selected memory cell MT_n. The select gate lines SG1_5a, SG1_5b, SG1_6a, and SG1_6b and the select gate lines SG2_2a and SG2_2b are each controlled to the selection potential (for example, 1.5 V), and the other select gate lines SG1_1a to SG1_4b, SG1_7a to SG1_8b and the other select gate lines SG2_1a, SG2_1b, SG2_3a, and SG2_3b are controlled to the non-selection potential (for example, 0 V).

As a result, each of the select transistors BT1_3 and BT2_7 of the drive unit DU_7 is selectively turned on, and the selection potential of the global bit line GBL is supplied to the selected memory cell MT_n of the drive unit DU_7 via the select transistors BT1_3 and BT2_7. Each of the select transistors ST1_3 and ST2_7 of the drive unit DU_7 is selectively turned on, and the selection potential of the global source line GSL is supplied to the selected memory cell MT_n of the drive unit DU_7 via the select transistors ST1_3 and ST2_7.

Accordingly, the channel region CH of the selected memory cell MT_n of the drive unit DU_7 is set to the selection potential (for example, −2.5 V), and in the selected memory cell MT_n, an electric field (for example, −5 V) exceeding a threshold at which the word line WL_n becomes negative with respect to the channel region CH toward the negative side is applied to the insulating film FE, and writing in which Vth shifts to the positive side occurs in the memory cell MT_n. “0” can be written to the memory cell MT_n of the drive unit DU_7. The memory cell MT_n of the drive unit DU_7 can hold “0” if the polarization state does not change due to an external electric field or the like.

At this time, in the unselected memory cells MT_1 to MT_n−1 of the drive unit DU_7, the selection potentials of the global bit line GBL and the global source line GSL are supplied, but an electric field (for example, 2.5 V) falling below the threshold to the positive side is applied to the insulating film FE, and writing does not occur in the memory cell MT.

Alternatively, in a case where an operation of reading the selected memory cell MT_n of the drive unit DU_7 is performed, the selection potential of the reading (for example, 1.5 V) is applied to the word line WL_n of the selected memory cell MT_n, and the non-selection potential (for example, 0 V) is applied to the word lines WL_1 to WL_n−1 of the unselected memory cells MT_1 to MT_n−1. The global bit line GBL is controlled to the selection potential of the reading (for example, 0.5 V), and the global source line GSL is controlled to the selection potential of the reading (for example, 0 V).

The select gate lines SG1_5a, SG1_5b, SG1_6a, and SG1_6b and the select gate lines SG2_2a and SG2_2b indicated by hatching in FIGS. 7 and 9 correspond to the selected memory cell MT_n. The select gate lines SG1_5a, SG1_5b, SG1_6a, and SG1_6b and the select gate lines SG2_2a and SG2_2b are each controlled to the selection potential (for example, 1.5 V), and the other select gate lines SG1_1a to SG1_4b, SG1_7a to SG1_8b and the other select gate lines SG2_1a, SG2_1b, SG2_3a, and SG2_3b are controlled to the non-selection potential (for example, 0 V).

As a result, each of the select transistors BT1_3 and BT2_7 of the drive unit DU_7 is selectively turned on, and the selection potential of the global bit line GBL is supplied to the selected memory cell MT_n of the drive unit DU_7 via the select transistors BT1_3 and BT2_7. Each of the select transistors ST1_3 and ST2_7 of the drive unit DU_7 is selectively turned on, and the selection potential of the global source line GSL is supplied to the selected memory cell MT_n of the drive unit DU_7 via the select transistors ST1_3 and ST2_7.

If “1” is written to the selected memory cell MT_n of the drive unit DU_7, a cell current flows from a conductive film BL to a conductive film SL in the channel region CH of the selected memory cell MT_n, and a potential of the conductive film BL decreases. The sense amplifier circuit 150 detects “1” according to the decrease in the potential of the conductive film BL. As a result, “1” is read from the selected memory cell MT_n of the drive unit DU_7. Alternatively, if “0” is written to the selected memory cell MT_n of the drive unit DU_7, the cell current hardly flows from the conductive film BL to the conductive film SL in the channel region CH of the selected memory cell MT_1, and the potential of the conductive film BL is maintained. The sense amplifier circuit 150 detects “0” according to the maintained potential of the conductive film BL. As a result, “0” is read from the selected memory cell MT_n of the drive unit DU_7.

At this time, in the unselected memory cells MT_1 to MT_n−1 of the selected drive unit DU_7, the selection potentials of the global bit line GBL and the global source line GSL are supplied, but the non-selection potential is supplied to the word lines WL_1 to WL_n−1. Therefore, in the unselected memory cells MT_1 to MT_n−1 of the selected drive unit DU_7, reading from the memory cells MT does not occur.

As described above, in the embodiment, in the semiconductor memory device 1, the selection mechanisms SM1 and SM2 of the memory cells MT are disposed between the substrate SB and the memory cell array 2 in the Z direction. As a result, in the manufacturing process for the semiconductor memory device 1, the structure of the array layer L3 is formed after the heat treatment at a relatively high temperature is completed. Therefore, it is possible to provide the structure of the semiconductor memory device 1 suitable for avoiding the heat treatment from being performed on each insulating film FE in a case where each insulating film FE includes the ferroelectric.

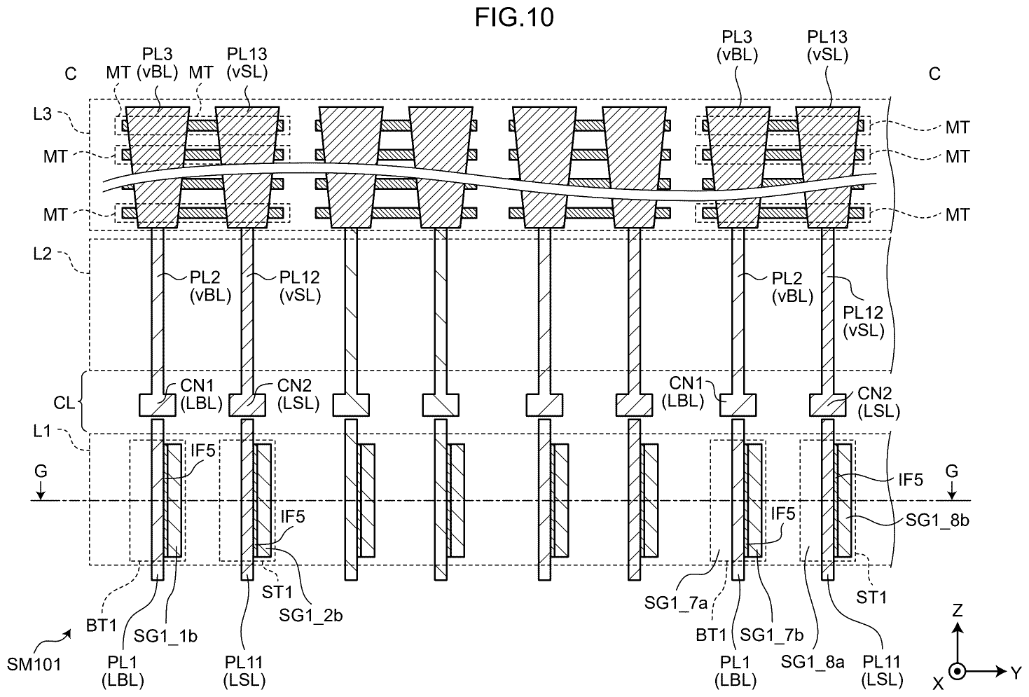

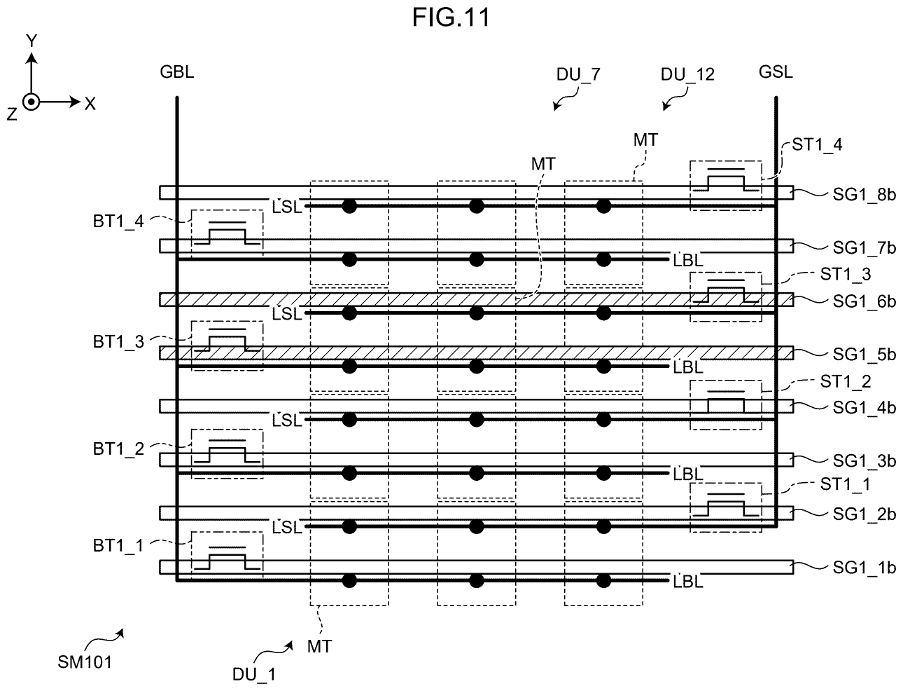

It should be noted that, as a first modified example of the embodiment, in a selection mechanism SM101, a conductive film functioning as the select gate line SG1 may be disposed on one side of each of the columnar bodies PL1 and PL11 in the Y direction as illustrated in FIGS. 10 and 11. FIG. 10 is a cross-sectional view illustrating configurations of the array layer L3, the select gate layer L2, and the select gate layer L1 along the Y-Z plane in the first modified example of the embodiment, and corresponds to a cross section taken along line C-C in FIG. 5. FIG. 11 is a plan view illustrating a configuration of the select gate layer L1 along the X-Y plane and corresponds to a cross section taken along line G-G in FIG. 10.

In the select gate layer L1, one of two conductive films disposed on both sides of each of the columnar bodies PL1 and PL11 in the Y direction is omitted in each select gate line SG1. FIGS. 10 and 11 illustrate a configuration in which the conductive film disposed on the −Y side among the two conductive films disposed on both sides of each of the columnar bodies PL1 and PL11 in the Y direction is omitted.

The select gate line SG1_1 illustrated in FIGS. 10 and 11 includes the conductive film SG1_1b. The select gate line SG1_2 includes the conductive film SG1_2b. The select gate line SG1_3 includes the conductive film SG1_3b. The select gate line SG1_4 includes the conductive film SG1_4b. The select gate line SG1_5 includes the conductive film SG1_5b. The select gate line SG1_6 includes the conductive film SG1_6b. The select gate line SG1_7 includes the conductive film SG1_7b. The select gate line SG1_8 includes the conductive film SG1_8b.

As the conductive film SG1_1b illustrated in FIG. 11 advances from the −X side to the +X side, the conductive film SG1_1b alternately approaches the +Y-side surface of the columnar body PL1 and the +Y-side surface of the columnar body PL11 multiple times. The insulating film IF5 is interposed between the conductive film SG1_1b and the columnar bodies PL1 and PL11 at positions close to the respective columnar bodies PL1 and PL11.

A portion of the columnar body PL1 that faces the conductive film SG1_1b via the insulating film IF5 functions as a select transistor BT1 in the selection mechanism SM101. The select transistor BT1 has a vertical thin film transistor (TFT) structure in which a channel region extends in the Z direction and a gate is provided on one side in the Y direction.

A portion of the columnar body PL11 that faces the conductive film SG1_1b via the insulating film IF5 functions as a select transistor ST1 in the selection mechanism SM101. The select transistor ST1 has a vertical thin film transistor (TFT) structure in which a channel region extends in the Z direction and a gate is provided on one side in the Y direction.

Each of the conductive film SG2_2b, the conductive film SG2_3b, the conductive film SG2_4b, the conductive film SG2_5b, the conductive film SG2_6b, the conductive film SG2_7b, and the conductive film SG2_8b is similar to the conductive film SG2_1b.

In this way, in the selection mechanism SM101, the conductive film functioning as the select gate line SG1 is disposed on one side of each of the columnar bodies PL1 and PL11 in the Y direction. As a result, a distance between the columnar bodies PL1 and PL11 in the Y direction can be decreased, and accordingly, a distance between the local bit line LBL and the local source line LSL in the Y direction can be decreased. As a result, an arrangement density of the select transistors BT1 and an arrangement density of the select transistors ST1 in the Y direction can be increased.

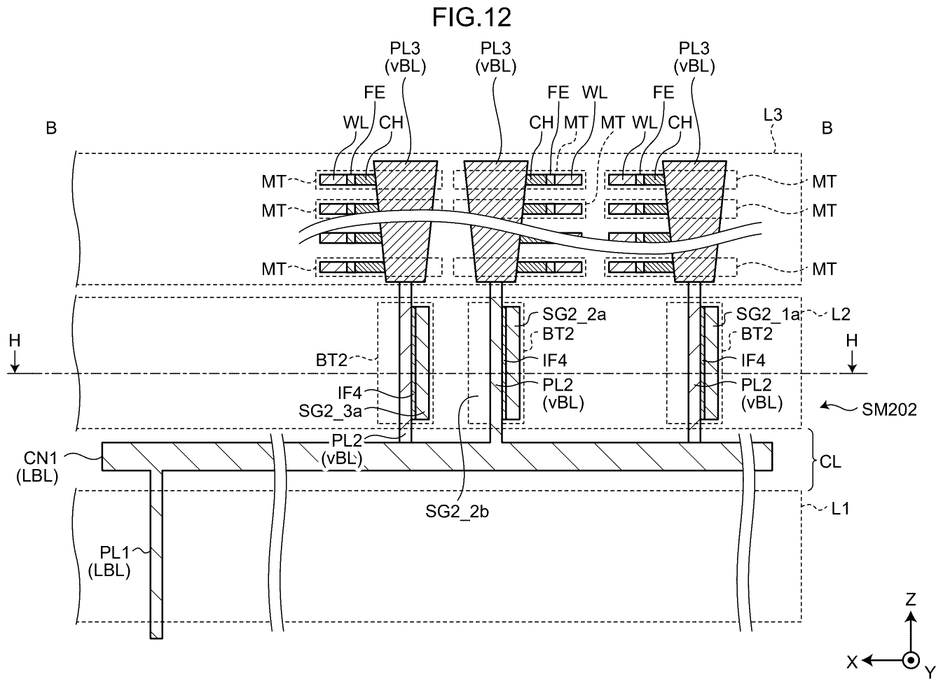

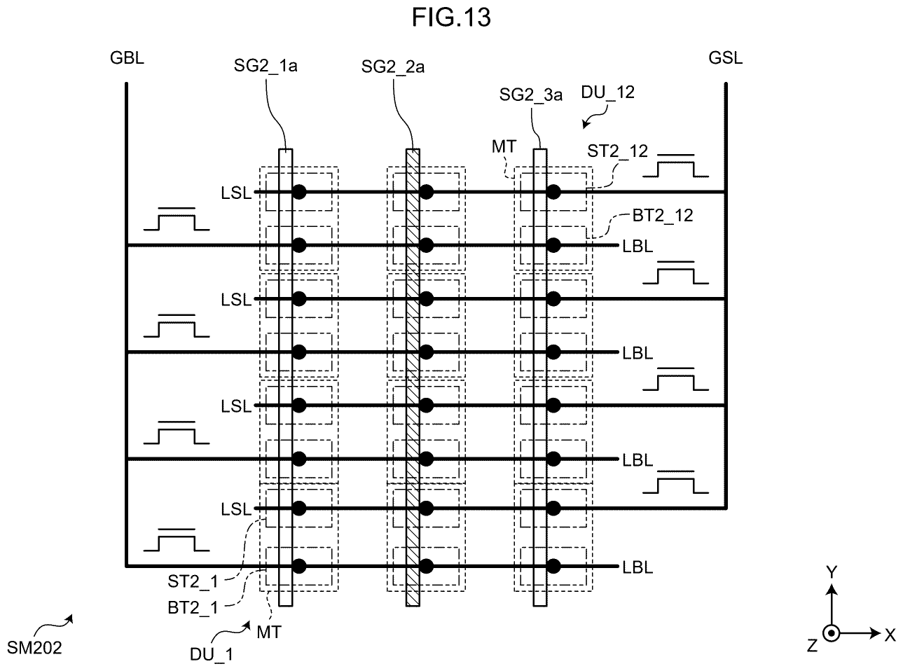

Alternatively, as a second modified example of the embodiment, in a selection mechanism SM202, a conductive film functioning as the select gate line SG2 may be disposed on one side of each of the columnar bodies PL2 and PL12 in the X direction as illustrated in FIGS. 12 and 13. FIG. 12 is a cross-sectional view illustrating configurations of the array layer L3, the select gate layer L2, and the select gate layer L1 along the Y-Z plane in the second modified example of the embodiment, and corresponds to a cross section taken along line B-B in FIG. 5. FIG. 13 is a plan view illustrating a configuration of the select gate layer L1 along the X-Y plane and corresponds to a cross section taken along line H-H in FIG. 12.

In the select gate layer L2, one of two conductive films disposed on both sides of each of the columnar bodies PL2 and PL12 in the X direction is omitted in each select gate line SG2. FIGS. 12 and 13 illustrate a configuration in which the conductive film disposed on the −Y side among the two conductive films disposed on both sides of each of the columnar bodies PL2 and PL12 in the X direction is omitted.

The select gate line SG2_1 illustrated in FIGS. 12 and 13 includes the conductive film SG2_1a. The select gate line SG2_2 includes the conductive film SG2_2a. The select gate line SG2_3 includes the conductive film SG2_3a.

As the conductive film SG2_1a illustrated in FIG. 13 advances from the −Y side to the +Y side, the conductive film SG2_1a alternately approaches a +Y-side surface of the columnar body PL2 and a +Y-side surface of the columnar body PL12 multiple times. The insulating film IF4 is interposed between the conductive film SG2_1a and the columnar bodies PL2 and PL12 at positions close to the respective columnar bodies PL2 and PL12.

A portion of the columnar body PL2 that faces the conductive film SG2_1a via the insulating film IF4 functions as a select transistor BT2 in the selection mechanism SM202. The select transistor BT2 has a vertical thin film transistor (TFT) structure in which a channel region extends in the Z direction and a gate is provided on one side in the X direction.

A portion of the columnar body PL12 that faces the conductive film SG2_1a via the insulating film IF4 functions as a select transistor ST2 in the selection mechanism SM202. The select transistor ST2 has a vertical thin film transistor (TFT) structure in which a channel region extends in the Z direction and a gate is provided on one side in the X direction.

It should be noted that each of the conductive film SG2_2a and the conductive film SG2_3a is similar to the conductive film SG2_1a.

In this way, in the selection mechanism SM202, the conductive film functioning as the select gate line SG2 is disposed on one side of each of the columnar bodies PL2 and PL12 in the X direction. As a result, a distance between the columnar bodies PL2 and PL12 in the X direction can be decreased. As a result, an arrangement density of the select transistors BT2 and an arrangement density of the select transistors ST2 in the X direction can be increased.

Alternatively, as a third modified example of the embodiment, in a selection mechanism SM301, a conductive film functioning as the select gate line SG1 may be divided into two layers.

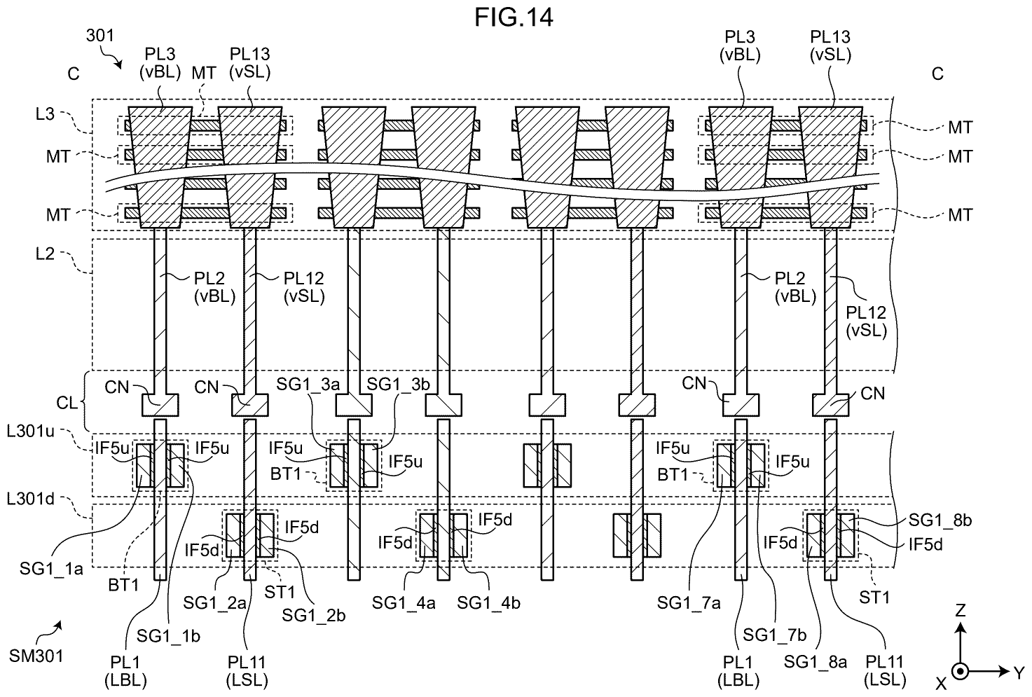

A semiconductor memory device 301 includes a select gate layer L301u and a select gate layer L301d as illustrated in FIG. 14 instead of the select gate layer L1 (see FIG. 8). FIG. 14 is a cross-sectional view illustrating configurations of the array layer L3, the select gate layer L2, the select gate layer L301u, and the select gate layer L301d along the Y-Z plane in the third modified example of the embodiment and corresponds to a cross section taken along line C-C in FIG. 5.

The select gate layer L301d is disposed between the substrate SB and the select gate layer L301u in the Z direction. The select gate layer L301u is disposed between the select gate layer L301d and the connection layer CL in the Z direction.

The selection mechanism SM301 is disposed in the select gate layer L301u and the select gate layer L301d in a divided manner. The selection mechanism SM301 includes a select transistor BT1 and a select transistor ST1. One of the select transistor BT1 and the select transistor ST1 is disposed in the select gate layer L301u, and the other is disposed in the select gate layer L301d. FIG. 14 illustrates a configuration in which the select transistor BT1 is disposed in the select gate layer L301u and the select transistor ST1 is disposed in the select gate layer L301d.

The multiple columnar bodies PL1, the odd-numbered select gate lines SG1_1, SG1_3, SG1_5, and SG1_7, and multiple insulating films IF5u are disposed in the select gate layer L301u.

The select gate line SG1_1 includes the multiple conductive films SG1_1a and SG1_1b. The select gate line SG1_3 includes the multiple conductive films SG1_3a and SG1_3b. The select gate line SG1_5 includes the multiple conductive films SG1_5a and SG1_5b. The select gate line SG1_7 includes the multiple conductive films SG1_7a and SG1_7b.

The multiple columnar bodies PL11, the even-numbered select gate lines SG1_2, SG1_4, SG1_6, and SG1_8, and multiple insulating films IF5d are disposed in the select gate layer L301d.

The select gate line SG1_2 includes the multiple conductive films SG1_2a and SG1_2b. The select gate line SG1_4 includes the multiple conductive films SG1_4a and SG1_4b. The select gate line SG1_6 includes the multiple conductive films SG1_6a and SG1_6b. The select gate line SG1_8 includes the multiple conductive films SG1_8a and SG1_8b.

The conductive films SG1_2a and SG1_2b are spaced apart from the conductive films SG1_1a and SG1_1b in the Y direction and also in the Z direction. Accordingly, an electric field interference between the conductive films SG1_2a and SG1_2b and the conductive films SG1_1a and SG1_1b can be suppressed.

The conductive films SG1_4a and SG1_4b are spaced apart from the conductive films SG1_3a and SG1_3b in the Y direction and also in the Z direction. Accordingly, an electric field interference between the conductive films SG1_4a and SG1_4b and the conductive films SG1_3a and SG1_3b can be suppressed.

The conductive films SG1_8a and SG1_8b are spaced apart from the conductive films SG1_7a and SG1_7b in the Y direction and also in the Z direction. Accordingly, an electric field interference between the conductive films SG1_8a and SG1_8b and the conductive films SG1_7a and SG1_7b can be suppressed.

In this way, in the selection mechanism SM301, the multiple conductive films functioning as the select gate lines SG1 are arranged while being spaced apart from each other in the Z direction in addition to the Y direction. As a result, an electric field interference between the multiple conductive films can be suppressed, and the distance between the columnar bodies PL1 and PL11 in the Y direction can be decreased. Accordingly, the distance between the local bit line LBL and the local source line LSL in the Y direction can be decreased. As a result, an arrangement density of the select transistors BT1 and an arrangement density of the select transistors ST1 in the Y direction can be increased.

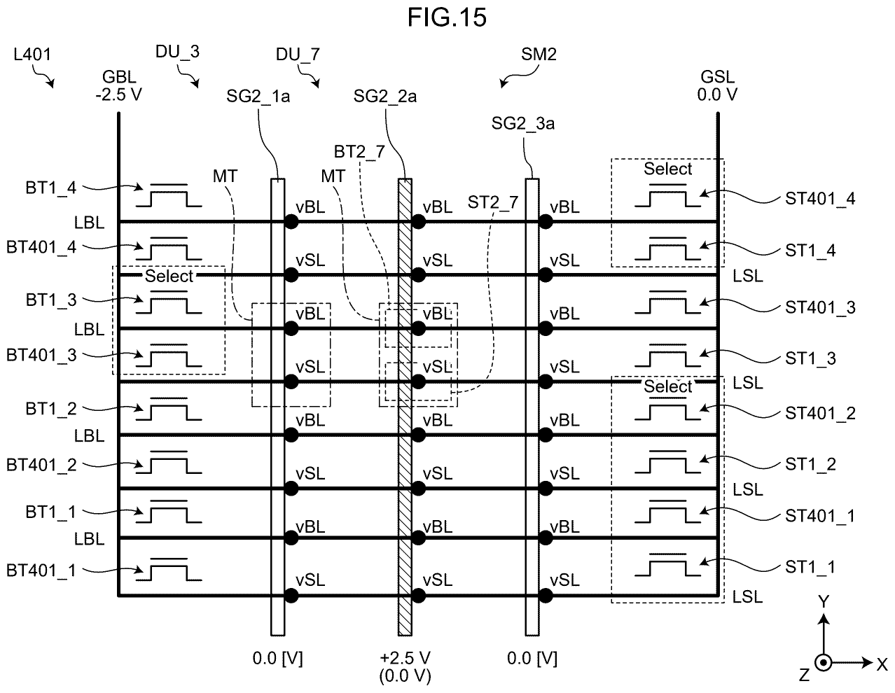

Alternatively, as a fourth modified example of the embodiment, a selection mechanism SM401 of a select gate layer L401 may be configured as illustrated in FIG. 15. FIG. 15 is a plan view illustrating a configuration of the select gate layer L401 and an operation of the select gate layer L401 when writing “1” according to the fourth modified example of the embodiment.

In the select gate layer L401, in addition to the select transistors BT1_1 to BT1_4 and the select transistors ST1_1 to ST1_4 (see FIG. 9), select transistors BT401_1 to BT401_4 and select transistors ST401_1 to ST401_4 are provided as the selection mechanism SM401.

A select transistor BT401 is connected between the local source line LSL and the global bit line GBL. The select transistor BT401 has a drain connected to the local source line LSL, a source connected to the global bit line GBL, and a gate connected to the select gate line SG1. The select transistor BT401 is driven via the select gate line SG1 connected to the gate of the select transistor BT401.

A select gate line SG401R connected to the gate of the select transistor BT401 and a select gate line SG1L connected to the select transistor ST1 positioned on a +X side thereof are separate from each other. As a result, the select transistor BT401 and the select transistor ST1 can be individually controlled to be turned on and off.

A select transistor ST401 is connected between the local bit line LBL and the global source line GSL. The select transistor ST401 has a drain connected to the local bit line LBL, a source connected to the global source line GSL, and a gate connected to the select gate line SG1. The select transistor ST401 is driven via a select gate line SG401 connected to the gate of the select transistor ST401.

A select gate line SG401L connected to the gate of the select transistor ST401 and a select gate line SG1R connected to the select transistor BT1 positioned on a −X side thereof are separate from each other. As a result, the select transistor ST401 and the select transistor BT1 can be individually controlled to be turned on and off.

In the memory cell group MG, the global bit line GBL is selectively connected in two stages by the select transistor BT1 and the select transistor BT2 or by the select transistor BT401 and the select transistor ST2. In the memory cell group MG, the global source line GSL is selectively connected in two stages by the select transistor ST1 and the select transistor ST2 or by the select transistor ST401 and the select transistor BT2. The memory cell MT in the selected memory cell group MG is selected by the word line WL.

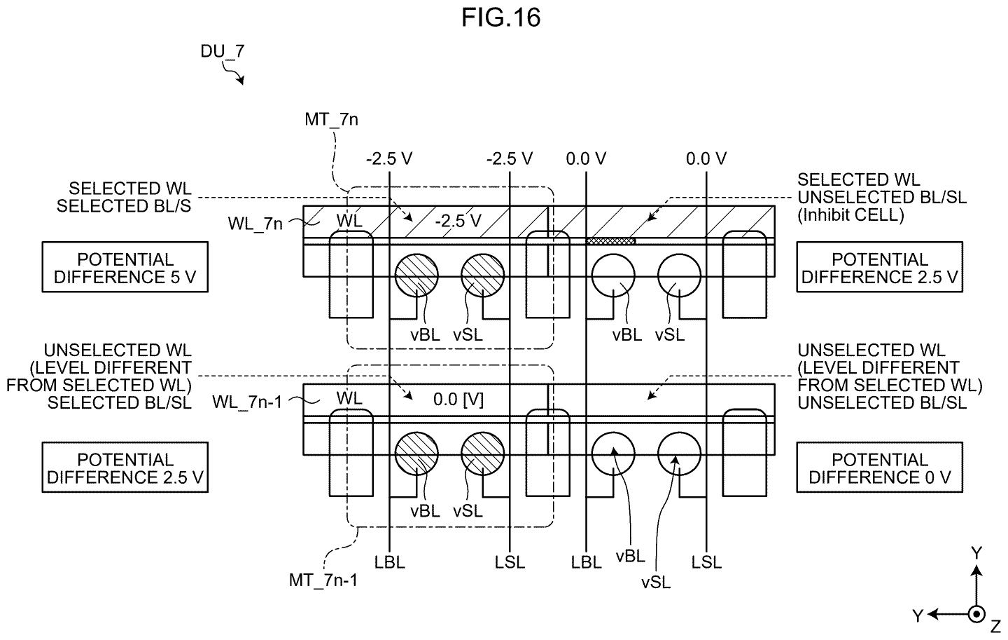

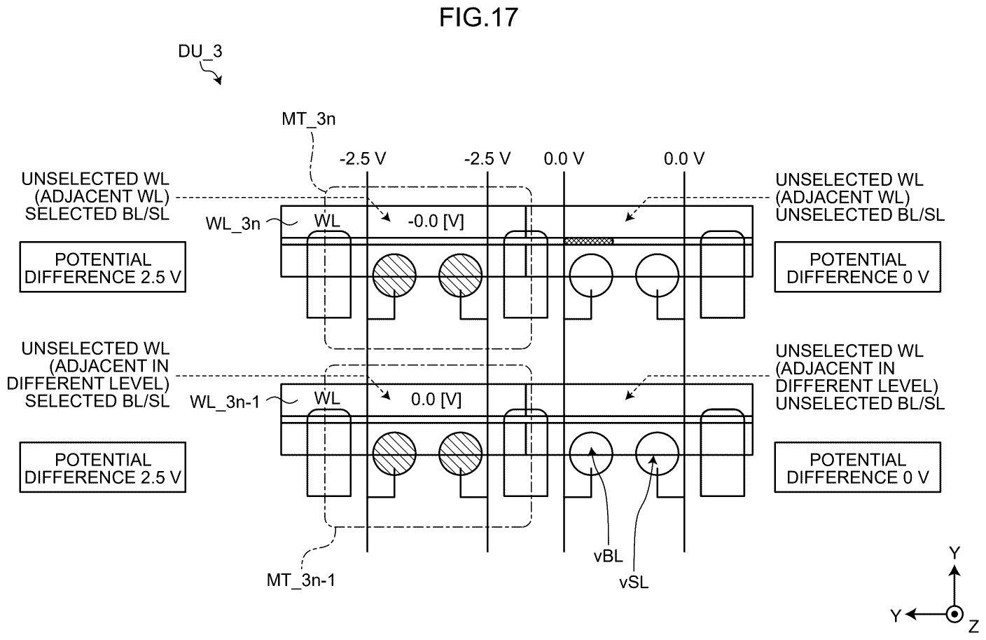

In a case where an operation of writing “1” to a selected memory cell MT_7n of the drive unit DU_7 is performed, the global bit line GBL is controlled to the selection potential of “1” (for example, −2.5 V), and the global source line GSL is controlled to the non-selection potential (for example, 0.0 V) as illustrated in FIG. 15. As illustrated in FIGS. 16 and 17, the selection potential of “1” (for example, +2.5 V) is applied to a word line WL_7n of the selected memory cell MT_7n, and the non-selection potential (for example, 0 V) is applied to word lines WL_7n−1, WL_3n, and WL_3n−1 of unselected memory cells MT_7n−1, MT_3n, and MT_3n−1.

Select gate lines SG1L_3 and SG401L_3 correspond to the selected memory cell MT_7n of the drive unit DU7. Each of the select gate lines SG1L_3 and SG401L_3 is controlled to the selection potential (for example, +2.5 V), and each of the other select gate lines is controlled to the non-selection potential (for example, 0 V).

The select gate line SG2_2a indicated by hatching in FIG. 15 is controlled to the selection potential (for example, +2.5 V), and each of the other select gate lines SG1_1a and SG1_3a is controlled to the non-selection potential (for example, 0.0 V).

As a result, on the −X side, each of the select transistors BT1_3 and BT2_7 of the drive unit DU_7 is selectively turned on, and the selection potential of the global bit line GBL is supplied to one end of the selected memory cell MT_7n of the drive unit DU_7 via the select transistors BT1_3 and BT2_7. Each of the select transistors BT401_3 and ST2_7 of the drive unit DU_7 is selectively turned on, and the selection potential of the global bit line GBL is supplied to the other end of the selected memory cell MT_7n of the drive unit DU_7 via the select transistors BT401_3 and ST2_7.

Accordingly, the channel region CH of the selected memory cell MT_7n of the drive unit DU_7 is set to the selection potential (for example, +2.5 V), and in the selected memory cell MT_7n of the drive unit DU_7, an electric field (for example, −5 V) exceeding a threshold at which the word line WL_7n becomes negative with respect to the channel region CH toward the negative side is applied to the insulating film FE, and writing in which Vth shifts to the negative side occurs in the memory cell MT. “1” can be written to the memory cell MT_7n of the drive unit DU_7. The memory cell MT_7n can hold “1” if the polarization state does not change due to an external electric field or the like.

At this time, in the unselected memory cell MT_7n−1 of the selected drive unit DU_7 and in MT_3n and MT_3n−1 of the unselected drive unit DU_3, the selection potential of the global bit line GBL is supplied, but an electric field (for example, −2.5 V) falling below the threshold to the negative side is applied to the insulating film FE, and writing does not occur in the memory cell MT.

Further, on the +X side, each of the select transistors ST1_1, ST401_1, ST1_2, ST1_402, ST1_4, and ST401_4 is selectively turned on, and the non-selection potential of the global source line GSL is supplied to the unselected memory cells MT via the select transistors ST1_1, ST401_1, ST1_2, ST1_402, ST1_4, and ST401_4. Since the non-selection potential is applied, writing does not occur in the memory cell MT.

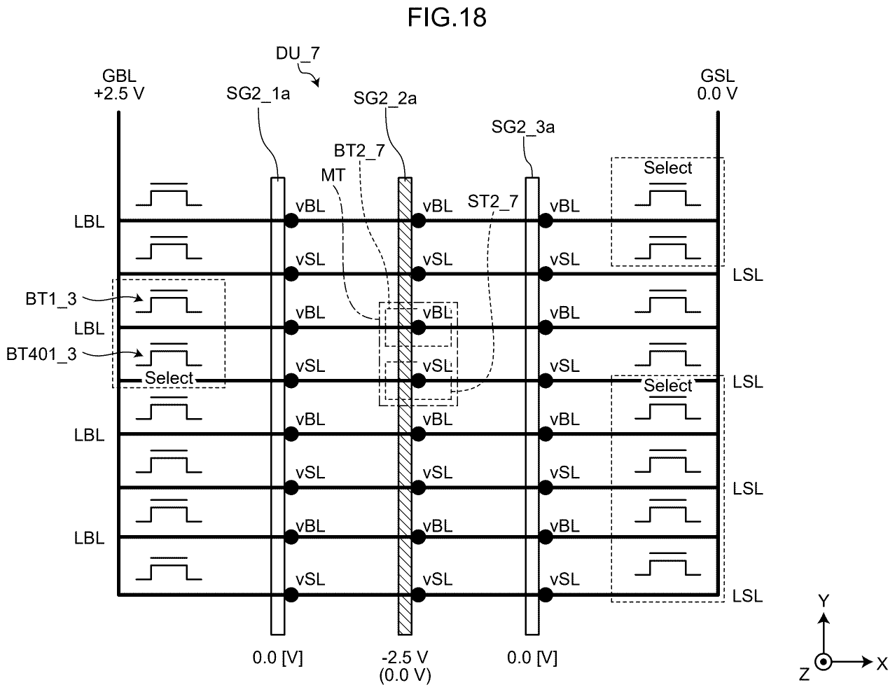

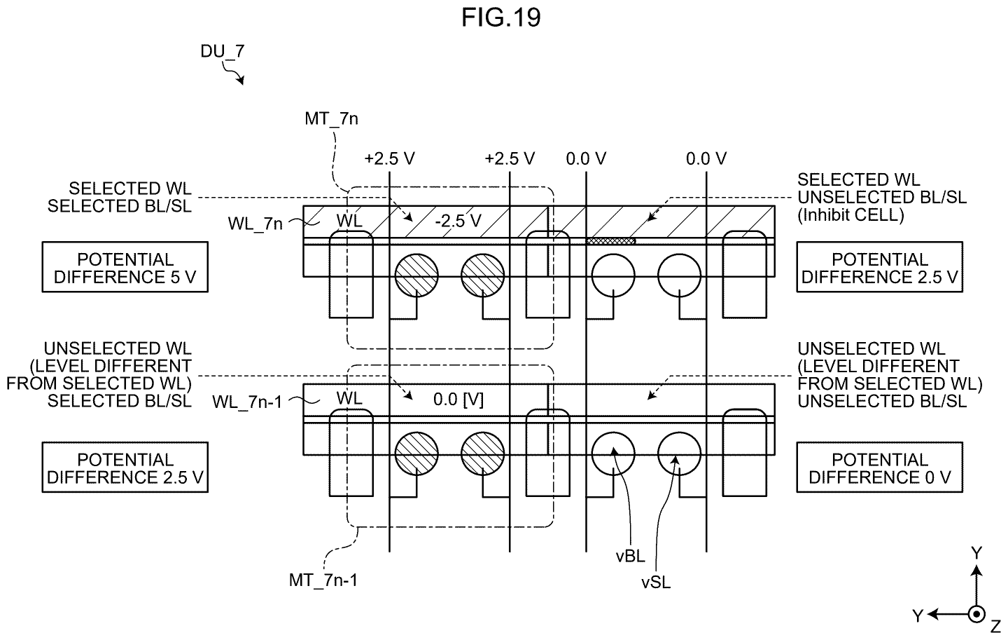

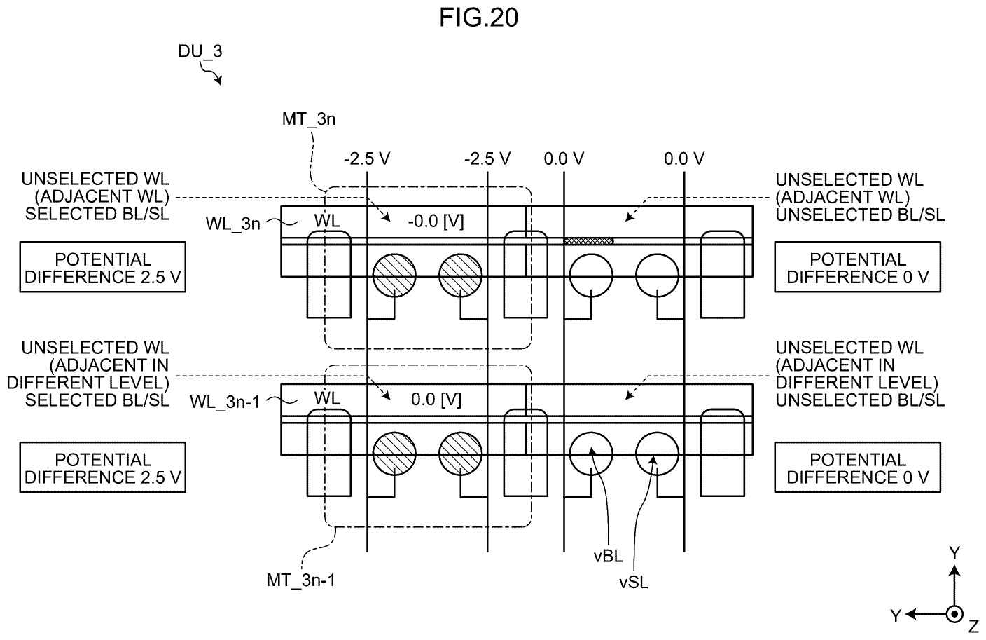

Alternatively, in a case where an operation of writing “0” to the selected memory cell MT_7n of the drive unit DU_7 is performed, the global bit line GBL is controlled to the selection potential of “0” (for example, +2.5 V), and the global source line GSL is controlled to the non-selection potential (for example, 0.0 V) as illustrated in FIG. 18. As illustrated in FIGS. 19 and 20, the selection potential of “1” (for example, +2.5 V) is applied to the word line WL_7n of the selected memory cell MT_7n, and the non-selection potential (for example, 0 V) is applied to the word lines WL_7n−1, WL_3n, and WL_3n−1 of the unselected memory cells MT_7n−1, MT_3n, and MT_3n-1.

The select gate lines SG1L_3 and SG401L_3 correspond to the selected memory cell MT_7n of the drive unit DU7. Each of the select gate lines SG1L_3 and SG401L_3 is controlled to the selection potential (for example, +2.5 V), and each of the other select gate lines is controlled to the non-selection potential (for example, 0 V).

The select gate line SG2_2a indicated by hatching in FIG. 18 is controlled to the selection potential (for example, −2.5 V), and each of the other select gate lines SG1_1a and SG1_3a is controlled to the non-selection potential (for example, 0.0 V).

As a result, on the −X side, each of the select transistors BT1_3 and BT2_7 of the drive unit DU_7 is selectively turned on, and the selection potential of the global bit line GBL is supplied to one end of the selected memory cell MT_7n of the drive unit DU_7 via the select transistors BT1_3 and BT2_7. Each of the select transistors BT401_3 and ST2_7 of the drive unit DU_7 is selectively turned on, and the selection potential of the global bit line GBL is supplied to the other end of the selected memory cell MT_7n of the drive unit DU_7 via the select transistors BT401_3 and ST2_7.

Accordingly, the channel region CH of the selected memory cell MT_7n of the drive unit DU_7 is set to the selection potential (for example, −2.5 V), and in the selected memory cell MT_7n of the drive unit DU_7, an electric field (for example, +5 V) exceeding a threshold at which the word line WL_7n becomes positive with respect to the channel region CH toward the positive side is applied to the insulating film FE, and writing in which Vth shifts to the positive side occurs in the memory cell MT. “0” can be written to the memory cell MT_7n of the drive unit DU_7. The memory cell MT_7n can hold “0” if the polarization state does not change due to an external electric field or the like.

At this time, in the unselected memory cell MT_7n−1 of the selected drive unit DU_7 and in MT_3n and MT_3n−1 of the unselected drive unit DU_3, the selection potential of the global bit line GBL is supplied, but an electric field (for example, +2.5 V) falling below the threshold to the positive side is applied to the insulating film FE, and writing does not occur in the memory cell MT.

Further, on the +X side, each of the select transistors ST1_1, ST401_1, ST1_2, ST1_402, ST1_4, and ST401_4 is selectively turned on, and the non-selection potential of the global source line GSL is supplied to the unselected memory cells MT via the select transistors ST1_1, ST401_1, ST1_2, ST1_402, ST1_4, and ST401_4. Since the non-selection potential is applied, writing does not occur in the memory cell MT.

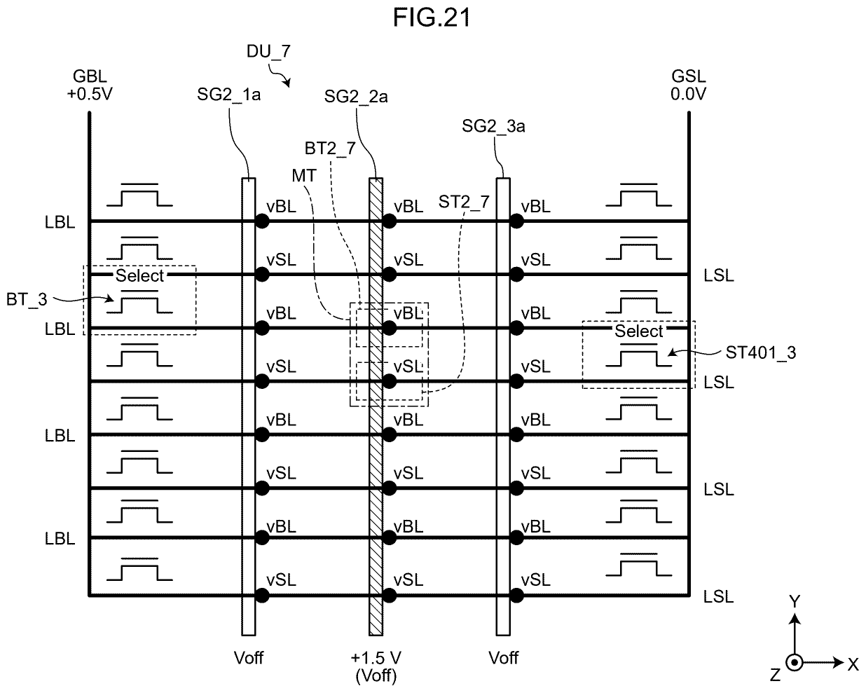

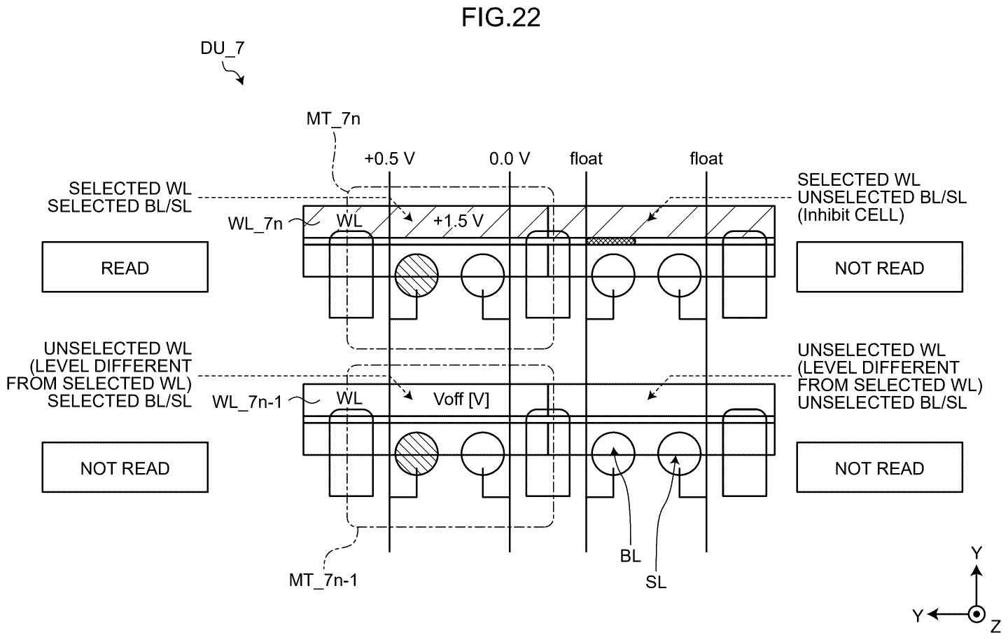

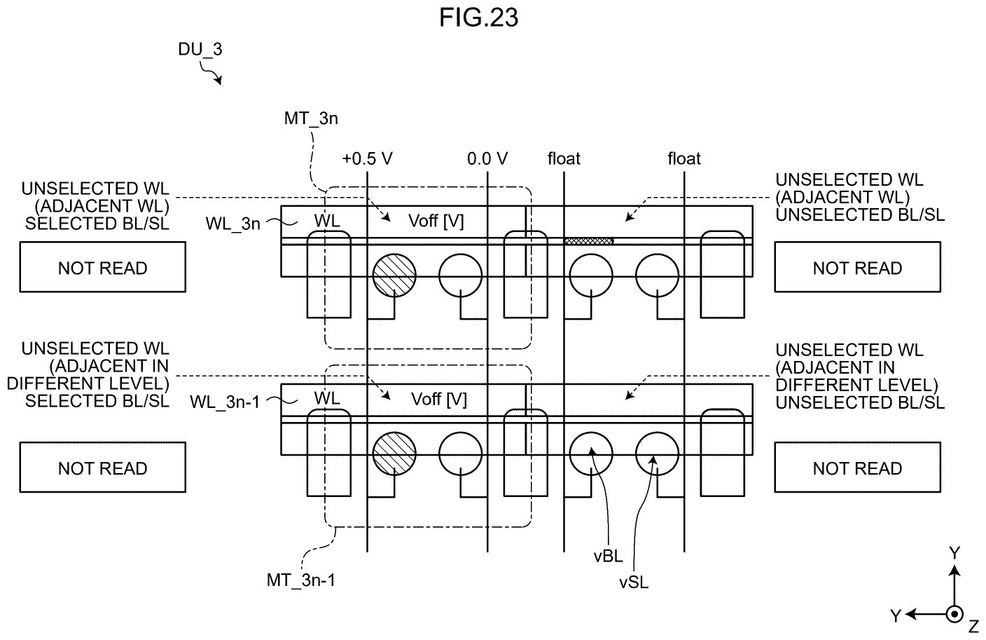

Alternatively, in a case where an operation of reading the selected memory cell MT_7n of the drive unit DU_7 is performed, the global bit line GBL is controlled to the selection potential of the reading (for example, +0.5 V), and the global source line GSL is controlled to the non-selection potential (for example, 0.0 V) as illustrated in FIG. 21. As illustrated in FIGS. 22 and 23, the selection potential of the reading (for example, +1.5 V) is applied to the word line WL_7n of the selected memory cell MT_7n, and the non-selection potential (for example, 0 V) is applied to the word lines WL_7n−1, WL_3n, and WL_3n−1 of the unselected memory cells MT_7n−1, MT_3n, and MT_3n-1.

The select gate lines SG1L_3 and SG401R_3 correspond to the selected memory cell MT_7n of the drive unit DU7. Each of the select gate lines SG1L_3 and SG401R_3 is controlled to the selection potential (for example, +2.5 V), and each of the other select gate lines is controlled to the non-selection potential (for example, 0 V).

The select gate line SG2_2a indicated by hatching in FIG. 21 is controlled to the selection potential (for example, +1.5 V), and each of the other select gate lines SG1_1a and SG1_3a is controlled to the non-selection potential (for example, 0.0 V).

As a result, on the −X side, each of the select transistors BT1_3 and BT2_7 of the drive unit DU_7 is selectively turned on, and on the +X side, each of the select transistors ST401_3 and ST2_7 of the drive unit DU_7 is selectively turned on. The selection potential of the global bit line GBL is supplied to one end of the selected memory cell MT_7n of the drive unit DU_7 via the select transistors BT1_3 and BT2_7, and the non-selection potential of the global source line GSL is supplied to the other end of the selected memory cell MT_7n of the drive unit DU_7 via the select transistors ST401_3 and ST2_7.

If “1” is written to the selected memory cell MT_7n of the drive unit DU_7, a cell current flows from the conductive film BL to the conductive film SL in the channel region CH of the selected memory cell MT_7n, and the potential of the conductive film BL decreases. The sense amplifier circuit 150 detects “1” according to the decrease in the potential of the conductive film BL. As a result, “1” is read from the selected memory cell MT_7n of the drive unit DU_7. Alternatively, if “0” is written to the selected memory cell MT_7n of the drive unit DU_7, the cell current hardly flows from the conductive film BL to the conductive film SL in the channel region CH of the selected memory cell MT_7n, and the potential of the conductive film BL is maintained. The sense amplifier circuit 150 detects “0” according to the maintained potential of the conductive film BL. As a result, “0” is read from the selected memory cell MT_7n of the drive unit DU_7.

At this time, in the unselected memory cell MT_7n−1 of the selected drive unit DU_7 and in MT_3n and MT_3n−1 of the unselected drive unit DU_3, the selection potential of the global bit line GBL and the non-selection potential of the global source line GSL are supplied to both ends, and the non-selection potential is supplied to the word lines WL_7n−1, WL_3n, and WL_3n−1. Therefore, reading from the memory cell MT does not occur in the unselected memory cell MT_7n−1 of the selected drive unit DU_7 and in MT_3n and MT_3n−1 of the unselected drive unit DU_3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
multiple first memory cells that are stacked above a substrate and connected in parallel between a first vertical bit line extending in a stacking direction and a first vertical source line extending in the stacking direction; and
a first selection mechanism that is disposed between the substrate and the multiple first memory cells in the stacking direction, selectively connects the first vertical bit line to a first local bit line, and selectively connects the first vertical source line to a first local source line.

2. The semiconductor memory device according to claim 1, further comprising
a second selection mechanism that is disposed between the substrate and the first selection mechanism in the stacking direction, selectively connects the first local bit line to a global bit line, and selectively connects the first local source line to a global source line.

3. The semiconductor memory device according to claim 1, wherein
the first local bit line extends in a first direction intersecting the stacking direction, and
the first local source line is aligned with the first local bit line in a second direction intersecting the stacking direction and the first direction and extends in the first direction.

4. The semiconductor memory device according to claim 2, wherein
the first local bit line extends in a first direction intersecting the stacking direction,
the first local source line is aligned with the first local bit line in a second direction intersecting the stacking direction and the first direction and extends in the first direction,
the global bit line extends in the second direction, and
the global source line is disposed on a side opposite to the global bit line with the second selection mechanism interposed between the global source line and the global bit line in the first direction, and extends in the second direction.

5. The semiconductor memory device according to claim 1, wherein
the first selection mechanism includes:
a first select transistor having a drain connected to the first vertical bit line and a source connected to the first local bit line; and
a second select transistor having a drain connected to the first vertical source line and a source connected to the first local source line.

6. The semiconductor memory device according to claim 2, wherein
the first selection mechanism includes:
a first select transistor having a drain connected to the first vertical bit line and a source connected to the first local bit line; and
a second select transistor having a drain connected to the first vertical source line and a source connected to the first local source line, and
the second selection mechanism includes:
a third select transistor having a drain connected to the first local bit line and a source connected to the global bit line; and
a fourth select transistor having a drain connected to the first local source line and a source connected to the global source line.

7. The semiconductor memory device according to claim 5, wherein
a gate of the first select transistor and a gate of the second select transistor are commonly connected to a first select gate line.

8. The semiconductor memory device according to claim 6, wherein
a gate of the first select transistor and a gate of the second select transistor are commonly connected to a first select gate line,
a gate of the third select transistor is connected to a second select gate line, and
a gate of the fourth select transistor is connected to a third select gate line.

9. The semiconductor memory device according to claim 7, wherein
the first local bit line extends in a first direction intersecting the stacking direction,
the first local source line is aligned with the first local bit line in a second direction intersecting the stacking direction and the first direction and extends in the first direction, and
the first select gate line is spaced apart from the first local bit line or the first local source line in the stacking direction and extends in the second direction.

10. The semiconductor memory device according to claim 8, wherein
the first local bit line extends in a first direction intersecting the stacking direction,
the first local source line is aligned with the first local bit line in a second direction intersecting the stacking direction and the first direction and extends in the first direction,
the first select gate line is spaced apart from the first local bit line or the first local source line in the stacking direction and extends in the second direction,
the global bit line extends in the first direction,
the global source line is disposed on a side opposite to the global bit line with the second selection mechanism interposed the global source line and the global bit line in the second direction, and extends in the first direction,
the second select gate line is spaced apart from the global bit line in the stacking direction and extends in the second direction, and
the third select gate line is spaced apart from the global source line in the stacking direction and extends in the second direction.

11. The semiconductor memory device according to claim 7, wherein
the first select transistor includes a first columnar body containing a semiconductor and extending in the stacking direction,
the second select transistor includes a second columnar body containing a semiconductor and extending in the stacking direction,
the first select transistor and the second select transistor are adjacent to each other in a second direction perpendicular to the stacking direction, and
the first select gate line includes a first conductive film extending in the second direction and covering each of a side surface of the first columnar body and a side surface of the second columnar body via an insulating film.

12. The semiconductor memory device according to claim 7, wherein
the first select transistor includes a first columnar body containing a semiconductor and extending in the stacking direction,
the second select transistor includes a second columnar body containing a semiconductor and extending in the stacking direction,
the first select transistor and the second select transistor are adjacent to each other in a second direction perpendicular to the stacking direction, and
the first select gate line includes:
a first conductive film extending in the second direction and covering each of a first side surface of the first columnar body and a second side surface of the second columnar body via an insulating film; and
a second conductive film extending in the second direction on an opposite side with the first select transistor and the second select transistor interposed between the first conductive film and the second conductive film and covering each of a first-second side surface of the first columnar body and a second-second side surface of the second columnar body via an insulating film.

13. The semiconductor memory device according to claim 8, wherein
the first select transistor includes a first columnar body containing a semiconductor and extending in the stacking direction,
the second select transistor includes a second columnar body containing a semiconductor and extending in the stacking direction,
the first select transistor and the second select transistor are adjacent to each other in a second direction perpendicular to the stacking direction,
the first select gate line includes a first conductive film extending in the first direction and covering each of a side surface of the first columnar body and a side surface of the second columnar body via an insulating film,
the third select transistor includes a third columnar body containing a semiconductor and extending in the stacking direction,
the fourth select transistor includes a fourth columnar body containing a semiconductor and extending in the stacking direction,
the third select gate line includes a third conductive film extending in a first direction perpendicular to the stacking direction and the second direction and covering a side surface of the third columnar body via an insulating film, and
the fourth select gate line includes a fourth conductive film extending in the second direction and covering a side surface of the third columnar body via an insulating film.

14. The semiconductor memory device according to claim 8, wherein
the first select transistor includes a first columnar body containing a semiconductor and extending in the stacking direction,
the second select transistor includes a second columnar body containing a semiconductor and extending in the stacking direction,
the first select transistor and the second select transistor are adjacent to each other in a second direction perpendicular to the stacking direction,
the first select gate line includes:
a first conductive film extending in the second direction and covering each of a first side surface of the first columnar body and a second side surface of the second columnar body via an insulating film; and
a second conductive film extending in the second direction on an opposite side with the first select transistor and the second select transistor interposed between the first conductive film and the second conductive film and covering each of a first-second side surface of the first columnar body and a second-second side surface of the second columnar body via an insulating film,
the third select gate line includes:
a third conductive film extending in a first direction perpendicular to the stacking direction and the second direction and covering a side surface of the third columnar body via an insulating film; and
a fifth conductive film extending in the second direction on an opposite side with the third select transistor interposed between the third conductive film and the fifth conductive film and covering a second side surface of the third columnar body via an insulating film, and
the fourth select gate line includes:
a fourth conductive film extending in the first direction and covering a side surface of the fourth columnar body via an insulating film; and
a sixth conductive film extending in the second direction on an opposite side with the fourth select transistor interposed between the fourth conductive film and the sixth conductive film and covering a second side surface of the fourth columnar body via an insulating film.

15. The semiconductor memory device according to claim 1, further comprising
multiple second memory cells that are stacked above the substrate, are adjacent to the multiple first memory cells in a first direction perpendicular to the stacking direction, and are connected in parallel between a second vertical bit line extending in the stacking direction and a second vertical source line extending in the stacking direction,
wherein the first selection mechanism is disposed between the substrate and the multiple second memory cells in the stacking direction, selectively connects the second vertical bit line to the first local bit line, and selectively connects the second vertical source line to the first local source line.

16. The semiconductor memory device according to claim 2, further comprising
multiple third memory cells that are stacked above the substrate, are adjacent to the multiple first memory cells in a second direction perpendicular to the stacking direction, and are connected in parallel between a third vertical bit line extending in the stacking direction and a third vertical source line extending in the stacking direction, wherein
the first selection mechanism is disposed between the substrate and the multiple third memory cells in the stacking direction, selectively connects the third vertical bit line to a second local bit line, and selectively connects the third vertical source line to a second local source line, and
the second selection mechanism selectively connects the second local bit line to the global bit line and selectively connects the second local source line to the global source line.

17. The semiconductor memory device according to claim 15, wherein
the first vertical bit line and the second vertical bit line are adjacent to each other in the first direction, and
the first vertical source line and the second vertical source line are adjacent to each other in the first direction.

18. The semiconductor memory device according to claim 16, wherein
the first vertical bit line and the third vertical bit line are adjacent to each other in the second direction, and
the first vertical source line and the third vertical source line are adjacent to each other in the second direction.

19. The semiconductor memory device according to claim 15, wherein
positions of the multiple first memory cells and the multiple second memory cells in the stacking direction correspond to each other, and
a control terminal of the first memory cell and a control terminal of the second memory cell whose positions in the stacking direction correspond to each other are connected to a common word line.

20. The semiconductor memory device according to claim 16, wherein
positions of the multiple first memory cells and the multiple third memory cells in the stacking direction correspond to each other, and
a control terminal of the first memory cell and a control terminal of the third memory cell whose positions in the stacking direction correspond to each other are connected to different word lines.
